(19) United States
(12) Patent Application Publication
(10) Pub. No.: US 2016/0079958 A1
(43) Pub. Date: Mar. 17, 2016

(54) ACOUSTIC RESONATOR COMPRISING VERTICALLY EXTENDED ACOUSTIC CAVITY

(71) Applicant: Avago Technologies General IP (Singapore) Pte. Ltd., Singapore (SG)

(72) Inventor: Dariusz Burak, Fort Collins, CO (US)

(21) Appl. No.: 14/953,545

(22) Filed: Nov. 30, 2015

Related U.S. Application Data
(63) Continuation-in-part of application No. 14/292,043, filed on May 30, 2014.

(51) Int. Cl. H03H 9/54

(52) U.S. Cl. CPC H03H 9/54

(57) ABSTRACT

An acoustic resonator device includes a substrate, a bottom electrode, a piezoelectric layer, and a top electrode. The top electrode includes a first top comb electrode having a first top bus bar and first top fingers extending in a first direction from the first top bus bar, and a second top comb electrode having a second top bus bar and second top fingers extending in a second direction from the second top bus bar, substantially opposite to the first direction, such that the first and second top fingers form a top interleaving pattern. One of the bottom and top electrodes is a composite electrode having a thickness of approximately λ/2, where λ is a wavelength corresponding to thickness extensional resonance frequency of the acoustic resonator. The piezoelectric layer and one of the bottom the electrodes that is not the composite electrode have a combined thickness of approximately λ/2.

### PRIORITY

The present application is a continuation-in-part (CIP) application under 37 C.F.R. §1.53(b) of commonly owned U.S. patent application Ser. No. 14/292,043, entitled “Acoustic Resonator Comprising Vertically Extended Acoustic Cavity,” filed on May 30, 2014, naming Dariusz Burak et al. as inventors (referred to as “parent application”). Priority to the parent application is claimed under 35 U.S.C. §120 and the disclosure of the parent application is hereby incorporated by reference in its entirety for all purposes.

### BACKGROUND

Acoustic resonators can be used to implement signal processing functions in various electronic applications. For example, some cellular phones and other communication devices use acoustic resonators to implement frequency filters for transmitted and/or received signals. Several different types of acoustic resonators can be used according to different applications, with examples including bulk acoustic wave (BAW) resonators such as thin film bulk acoustic resonators (FBARs), stacked bulk acoustic resonators (SBARs), double bulk acoustic resonators (DBARs), contour mode resonators (CMRs), and solidly mounted resonators (SMRs). An FBAR, for example, includes a piezoelectric layer between a bottom (first) electrode and a top (second) electrode over a cavity. BAW resonators may be used in a wide variety of electronic applications and devices, such as cellular telephones, personal digital assistants (PDAs), electronic gaming devices, laptop computers and other portable communications devices. For example, FBARs operating at frequencies close to their fundamental resonance frequencies may be used as a key component of radio frequency (RF) filters and duplexers in mobile devices, including ladder filters, for example. Other types of filters formed of acoustic resonators include laterally coupled resonator filters (LCRFs) and coupled resonator filters (CRFs), for example.

A typical conventional acoustic resonator (e.g., FBAR) includes a piezoelectric layer of piezoelectric material applied to a top surface of a bottom electrode, and a top electrode applied to a top surface of the piezoelectric layer, resulting in a structure referred to as an acoustic stack. The acoustic stack is formed on a substrate over a cavity in the substrate. Where an input electrical signal is applied between the bottom and top electrodes, reciprocal or inverse piezoelectric effect causes the acoustic stack to mechanically expand or contract depending on the polarization of the piezoelectric material. As the input electrical signal varies over time, expansion and contraction of the acoustic stack produces acoustic waves that propagate through the acoustic resonator in various directions and are converted into an output electrical signal by the piezoelectric effect. Some of the acoustic waves achieve resonance across the acoustic stack, with the resonant frequency being determined by factors such as the materials, dimensions, and operating conditions of the acoustic stack. These and other mechanical characteristics of the acoustic resonator determine its frequency response.

Generally, a conventional acoustic resonator, such as an FBAR, may be designed to operate at high frequencies, such as approximately 3.6 GHz, for example. In this case, each of the bottom and top electrodes would be formed of tungsten (W) approximately 2700 Å thick top, and the piezoelectric layer 130 would be formed of aluminum nitride (AlN) approximately 1600 Å thick. Conventionally, aggregate thickness of the acoustic stack of such an FBAR is one half the wavelength λ (or λ/2) corresponding to the thickness extensional resonance frequency of the FBAR. A conventional acoustic resonator generally suffers from a number of issues when designed for operation at high frequencies. For example, an FBAR would tend of have a low quality factor (Q-factor) due to high series resistance Rs resulting from the relatively thin bottom and top electrodes. The FBAR would also tend to have low parallel resistance Rp due to the relatively thin piezoelectric layer, resulting in small area. Furthermore, the piezoelectric layer would be susceptible to electro-static discharge (ESD) failures due to large electric fields, low RF power level failures due to the small area and resulting high RF-power density, and large perimeter-to-area loss due to small overall device area.

For example, acoustic resonators are generally designed to meet a specific characteristic electrical impedance Z₀ requirement. The characteristic electrical impedance Z₀ is proportional to the resonator area and inversely proportional to the desired frequency of operation and thickness of the piezoelectric layer. The thickness of the piezoelectric layer is predominantly determined by the desired frequency of operation, but also by the desired electromechanical coupling coefficient kt². Within applicable limits, the electromechanical coupling coefficient kt² is proportional to thickness of the piezoelectric layer and inversely proportional to thicknesses of the bottom and top electrodes. More specifically, the electromechanical coupling coefficient kt² is proportional to the fraction of acoustic energy stored in the piezoelectric layer and inversely proportional to the fraction of acoustic energy stored in the electrodes. Thus, for a predetermined impedance Z₀, the resonator size, and therefore its cost, may be reduced by using piezoelectric material with higher intrinsic electromechanical coupling coefficient kt² (for instance, aluminum nitride doped with scandium), as it allows use of a thinner piezoelectric layer (and therefore reduction of the resonator area) at the expense of increasing thicknesses of the bottom and top electrodes in order to maintain the desired resonance frequency. Therefore, as mentioned above, for high-frequency applications, specific electromechanical coupling coefficient kt², impedance Z₀ and operating frequency requirements will enforce reduction of the active area and piezoelectric layer thickness, and the resulting reduction of the overall Q-factor of the device and the robustness to ESD and high RF-power failures. Therefore approaches are needed to increase the device area and piezoelectric material thickness, while preserving electromechanical coupling coefficient kt², impedance Z₀ and operating frequency as determined by a specific application.

### BRIEF DESCRIPTION OF THE DRAWINGS

The illustrative embodiments are best understood from the following detailed description when read with the accompanying drawing figures. It is emphasized that the various features are not necessarily drawn to scale. In fact, the dimensions may be arbitrarily increased or decreased for clarity of discussion. Wherever applicable and practical, like reference numerals refer to like elements.

FIG. 1 is a top plan view of a single-ended laterally coupled resonator filter (LCRF) device with distributed Bragg electrodes (DBEs), according to a representative embodiment.

FIGS. 2A-2D are cross-sectional diagrams, taken along line A-A′ of FIG. 1, illustrating the single-ended LCRF device, according to various representative embodiments.

FIG. 3 is a top plan view of a differential LCRF device with DBEs, according to a representative embodiment.

FIGS. 4A-4D are cross-sectional diagrams, taken along line A-A′ of FIG. 1, illustrating the differential LCRF device, according to various representative embodiments.

FIG. 5 is a top plan view of a lateral-field-excitation (LFE) contour mode resonator (CMR) device with DBEs, according to a representative embodiment.

FIGS. 6A-6D are cross-sectional views of the LFE-CMR device in FIG. 5 taken along a line A-A′, according to various representative embodiments.

FIG. 7A is a top plan view of a LFE-CMR device with DBEs and without a bottom metal layer, according to a representative embodiment.

FIG. 7B is a cross-sectional view of the LFE-CMR device in FIG. 7A taken along a line A-A′, according to the representative embodiment.

FIG. 8 is a top plan view of a thickness-field-excitation (TFE) contour mode resonator (CMR) device with DBEs, according to a representative embodiment.

FIGS. 9A-9D are cross-sectional views of the TFE-CMR device in FIG. 8 taken along a line A-A′, according to various representative embodiments.

### DETAILED DESCRIPTION

In the following detailed description, for purposes of explanation and not limitation, example embodiments disclosing specific details are set forth in order to provide a thorough understanding of the present teachings. However, it will be apparent to one having ordinary skill in the art having the benefit of the present disclosure that other embodiments according to the present teachings that depart from the specific details disclosed herein remain within the scope of the appended claims. Moreover, descriptions of well-known apparatuses and methods may be omitted so as to not obscure the description of the example embodiments. Such methods and apparatuses are clearly within the scope of the present teachings.

The terminology used herein is for purposes of describing particular embodiments only, and is not intended to be limiting. The defined terms are in addition to the technical, scientific, or ordinary meanings of the defined terms as commonly understood and accepted in the relevant context.

The terms “a”, “an” and “the” include both singular and plural referents, unless the context clearly dictates otherwise. Thus, for example, “a device” includes one device and plural devices. The terms “substantial” or “substantially” mean to within acceptable limits or degree. The term “approximately” means to within an acceptable limit or amount to one of ordinary skill in the art. Relative terms, such as “above,” “below,” “top,” “bottom,” “upper” and “lower” may be used to describe the various elements' relationships to one another, as illustrated in the accompanying drawings. These relative terms are intended to encompass different orientations of the device and/or elements in addition to the orientation depicted in the drawings. For example, if the device were inverted with respect to the view in the drawings, an element described as “above” another element, for example, would now be below that element. Where a first device is said to be connected or coupled to a second device, this encompasses examples where one or more intermediate devices may be employed to connect the two devices to each other. In contrast, where a first device is said to be directly connected or directly coupled to a second device, this encompasses examples where the two devices are connected together without any intervening devices other than electrical connectors (e.g., wires, bonding materials, etc.).

The present teachings relate generally to acoustic resonators and acoustic resonator filters with distributed Bragg electrodes (DBEs). The teachings include LCRF devices with DBEs, LFE-CMR devices with DBEs, and TFE-CMR devices with DBEs, for example.

According to a representative embodiment, an acoustic resonator device includes a substrate, a bottom electrode disposed on an acoustic reflector formed in or on the substrate, a piezoelectric layer disposed over the bottom electrode, and a top electrode disposed over the piezoelectric layer. The top electrode includes a first top comb electrode having a first top bus bar and multiple first top fingers extending in a first direction from the first top bus bar, and a second top comb electrode having a second top bus bar and multiple top fingers extending in a second direction from the second top bus bar, the second direction being substantially opposite to the first direction such that the first and second top fingers form a top interleaving pattern. One of the bottom electrode and the top electrode is a composite electrode having a thickness of approximately λ/2, where λ is a wavelength corresponding to a thickness extensional resonance frequency of the acoustic resonator. Such composite electrode may be referred to as a distributed Bragg electrode (DBE). The piezoelectric layer and one of the bottom electrode and the top electrode that is not the composite electrode have a combined thickness of approximately λ/2. In this context, and through this disclosure, “approximately” is intended to cover a range of thicknesses around λ/2, e.g., from about 2λ/5 (or λ/2−20 percent) to about 3λ/5 (or λ/2+20 percent), but such that the overall thickness of the acoustic stack of the resonator device is an integer multiple of λ/2.

According to a representative embodiment, an acoustic resonator device includes a substrate, a bottom electrode disposed on an acoustic reflector formed in or on the substrate, a piezoelectric layer disposed over the bottom electrode, and a top electrode disposed over the piezoelectric layer. The top electrode includes a first top comb electrode having a first top bus bar and multiple first top fingers extending in a first direction from the first top bus bar, and a second top comb electrode having a second top bus bar and multiple second top fingers extending in a second direction from the second top bus bar, the second direction being substantially opposite to the first direction such that the first and second top fingers form a top interleaving pattern. Each of the bottom electrode and the top electrode is a composite electrode having a thickness of approximately λ/2, where λ is a wavelength corresponding to a thickness extensional resonance frequency of the acoustic resonator. The piezoelectric layer has a thickness of approximately λ/2.

The described embodiments may provide several potential benefits relative to conventional technologies. For example, representative embodiment of acoustic filters described below may be produced with a smaller die size compared with conventional acoustic filters. This results in reduction of a number of factors, such as footprint, power consumption, and cost. Certain embodiments can also be used to efficiently implement common circuit functions, such as single-ended to differential signal conversion or impedance transformation. In addition, certain embodiments can be used to implement electrical components for wide band applications. Finally, various benefits can be achieved in certain embodiments by a relatively simple structure and corresponding fabrication process, as will be apparent from the following description. Also, while the overall thickness of the acoustic stack in terms of λ/2 multiples may be determined by the presence of air on both bottom and top sides of the acoustic stack, the partitioning of a particular layer thickness enables design of the electromechanical coupling coefficient kt² and the series resonance frequency Fs to application-determined target values. On the other hand, keeping the piezoelectric layer and electrode thicknesses close to the λ/2 value may be beneficial for overall device performance.

In general, mechanical motion in a LCRF may be excited from electrical signal by two mechanisms simultaneously. The first one is analogous to mechanical motion excitation in bulk acoustic wave (BAW) resonators, that is by vertical component of the electric field between the top and bottom electrodes. The frequency response of this mechanism is determined by the overall thickness of the acoustic stack in terms of λ/2 multiples of the thickness extensional modes. The second mechanism is analogous to mechanical motion excitation in surface acoustic wave (SAW) resonators, that is by lateral component of the electric field between the fingers of the top electrode. The frequency response of this mechanism is determined by the spacing or gaps between the fingers in terms of λ/2 multiples of lateral eigen-modes (so called Lamb modes of the acoustic stack). Experimental and numerical evidence (not shown here) indicates that in general the LCRF pass-band is close to fundamental resonance frequency Fs of the acoustic stack, which further indicates that the former mechanism of mechanical motion excitation from the electric field dominates at least for some designs. However, the presence of spurious resonances outside of the main passband indicates that the latter mechanism of mechanical motion excitation from the electric field may be present as well.

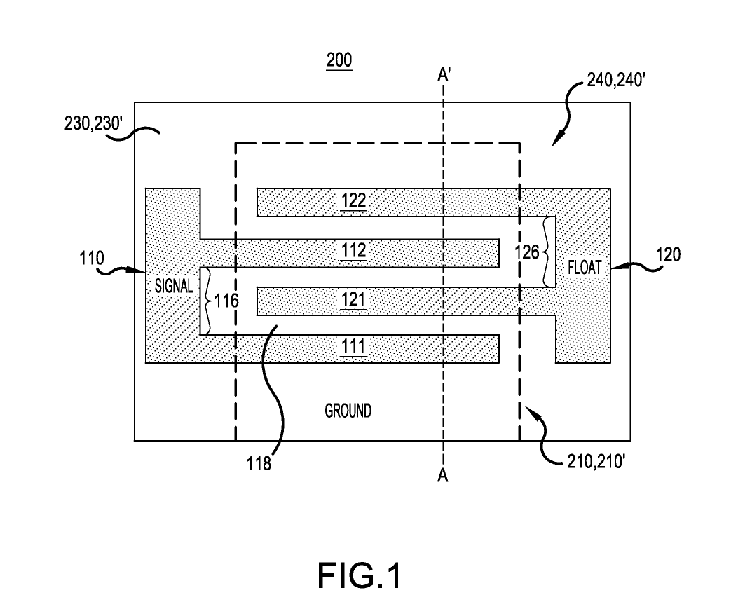

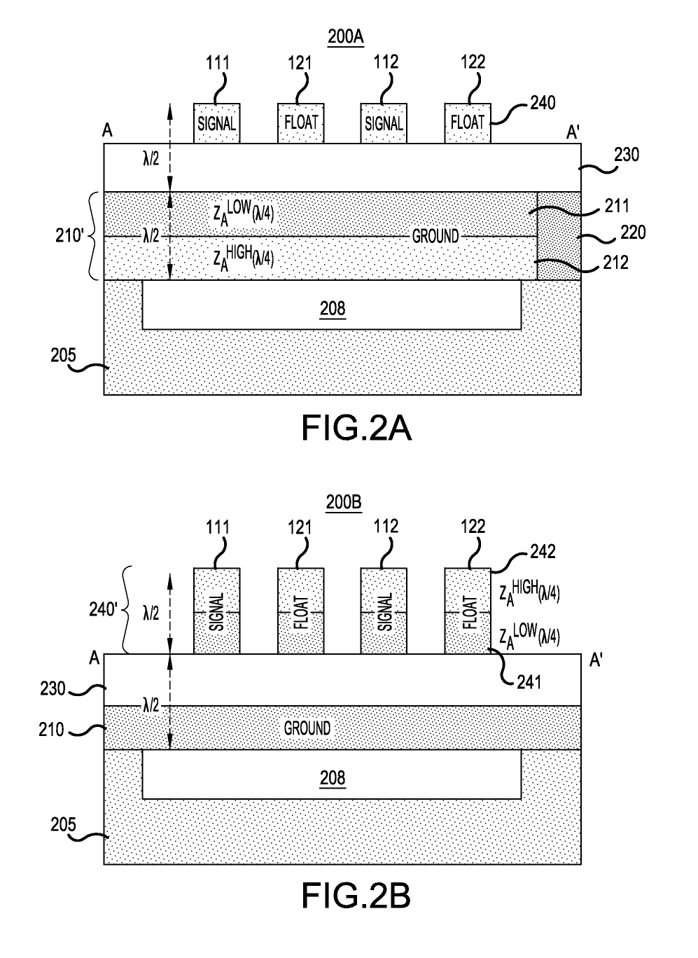

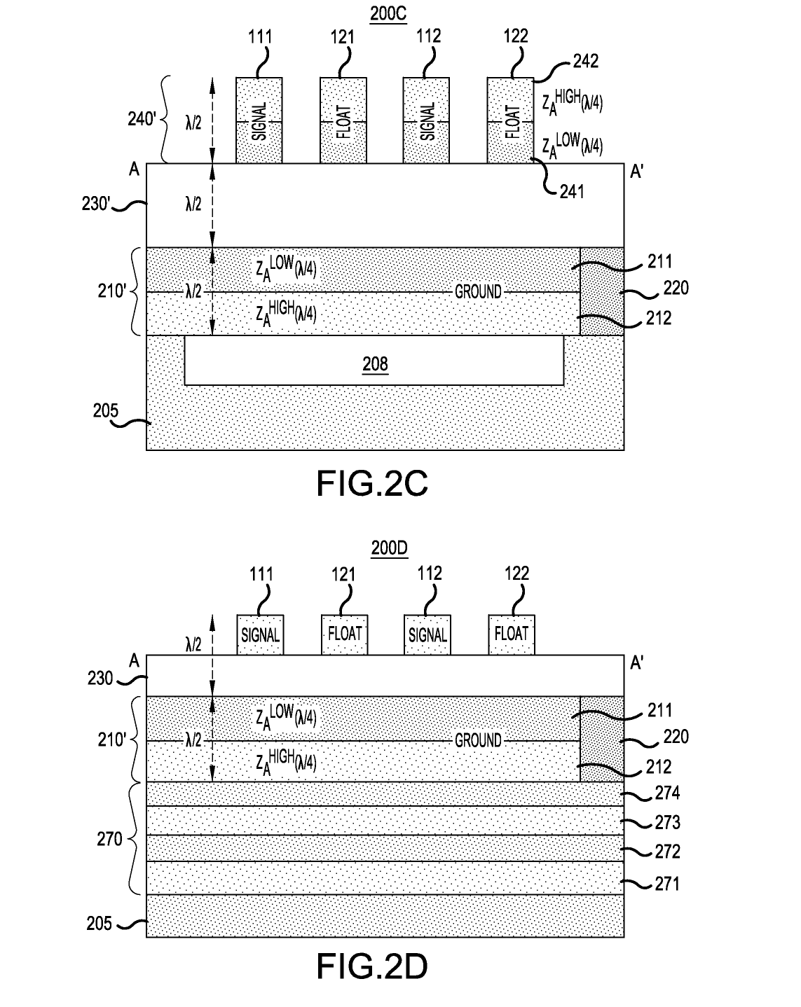

FIG. 1 is a top plan view of a laterally coupled resonator filter (LCRF) device with at least one distributed Bragg electrode (DBE), according to a representative embodiment, and FIGS. 2A-2D are cross-sectional views of the LCRF in FIG. 1 taken along a line A-A′ according to different embodiments. More particularly, FIG. 1 depicts LCRF device 200, which is a single-ended LRCF (as opposed a differential LCRF, discussed below). The cross-sectional views correspond to different variations of the single-ended LCRF device 200, respectively, as LCRF devices 200A-200D. The LCRF devices 200A-200D, which are acoustic resonators, and have many of the same features, so a repetitive description of these features may be omitted in an effort to avoid redundancy.

Referring to FIG. 1, LCRF device 200 includes a top electrode 240, which may be referred to as a contour electrode, comprising a first top comb electrode 110 and second top comb electrode 120. The first top comb electrode 110 includes a first top bus bar 115 and multiple first top comb extensions or first top comb-like fingers, indicated by representative first top fingers 111 and 112, separated by first space 116. The first top fingers 111 and 112 extend in a first direction from the first top bus bar 115 (e.g., left to right in the illustrative orientation). The second top comb electrode 120 similarly includes a second top bus bar 125 and multiple second top comb extensions or top comb-like fingers, indicated by representative second top fingers 121 and 122, separated by second space 126. The second top fingers 121 and 122 extend in a second direction, opposite the first direction, from the second top bus bar 125 (e.g., right to left in the illustrative orientation). The first top comb electrode 110 is a signal electrode to which an electrical signal is applied, and the second top comb electrode 120 is a floating electrode providing an output for the electrical signal.

The top electrode 240 is interdigitated in that the first top finger 112 of the first top comb electrode 110 extends into the second space 126 between the second top fingers 121 and 122 of the second top comb electrode 120, and the second top finger 121 of the second top comb electrode 120 extends into the first space 116 between the first top fingers 111 and 112 of the first top comb electrode 110. This arrangement forms a top interleaving pattern of the LCRF device 200. The alternating first and second top fingers 111, 121, 112 and 122 are likewise separated by spaces or gaps 118, respectively. In the depicted embodiment, a top surface of a piezoelectric layer 230, 230′ is visible through the gaps 118. Also, in the depicted embodiment, the edges of the first top fingers 111, 112 and the second top fingers 121, 122 are parallel to one another. This includes the side (long) edges of the first top fingers 111, 112 and the second top fingers 121, 122 that extend lengthwise along first and second directions, respectively, as well as the end (short) edges that are perpendicular to the side edges, respectively.

FIGS. 2A to 2D are cross-sectional diagrams, taken along line A-A′ of FIG. 1, illustrating LCRF devices, according to representative embodiments. Each of the LCRF devices shown in FIGS. 2A to 2D includes a single bottom electrode (although having multiple layers, in certain configurations), thus depicting a single-ended LCRF configuration.

Referring to FIG. 2A, LCRF device 200A includes a substrate 205 defining a cavity 208 (e.g., air cavity), which serves as an acoustic reflector. The LCRF device 200A further includes a composite bottom electrode 210′ disposed on the substrate 205 over the cavity 208, a planarization layer 220 (optional) disposed adjacent to bottom electrode 210′ on the substrate 205, a piezoelectric layer 230 disposed on the composite bottom electrode 210′ and the planarization layer 220, and a top (contour) electrode 240 disposed over the piezoelectric layer 230.

The composite bottom electrode 210′ is referred to as “composite” because it comprises (at least) two layers formed of different metal materials. More particularly, in reference to proximity to the piezoelectric layer 230, the composite bottom electrode 210′ includes first bottom electrode layer 211 adjacent the piezoelectric layer 230 and second bottom electrode layer 212 adjacent the first bottom electrode layer 211. Generally, the first bottom electrode layer 211 is formed of a material having a relatively low acoustic impedance (indicated throughout as Z_{A}^{LOW}), such as aluminum (Al), titanium (Ti) or beryllium (Be), while the second bottom electrode layer 212 is formed of a material having a relatively high acoustic impedance (indicated throughout as Z_{A}^{HIGH}), such as tungsten (W), iridium (Ir) or molybdenum (Mo). Accordingly, the composite bottom electrode 210′ may function as an acoustic mirror, such as a distributed Bragg reflector (DBR), as a practical matter. Of course, the composite electrodes throughout the subject disclosure may comprise additional layers and/or different materials, in various embodiments, without departing from the scope of the present teachings.

Collectively, composite bottom electrode 210′, the piezoelectric layer 230, and the top electrode 240 constitute an acoustic stack of the LCRF device 200A. Also, overlapping portions of the composite bottom electrode 210′, the piezoelectric layer 230, and the top electrode 240 over the cavity 208 define a main membrane region of the LCRF device 200A, where the cavity 208 enables movement (or vibration) of the piezoelectric layer 230 in a vertical (as opposed to lateral) direction. Notably, reference to the cavity 208 implies that it is “filled” with air. However, this terminology is used for the sake of convenience and is not intended to be limiting. That is, it is understood that the cavity 208 may constitute a vacuum, be filled with one or more gases other than air, or be filled with dielectric or metal material, to provide the desirably large acoustic impedance discontinuity depending on the specific implementation, without departing from the scope of the present teachings.

The LCRF device 200A is designed for high frequencies (e.g., 3.5 GHz and above). Accordingly, the acoustic cavity of the LCRF device 200A is vertically extended, e.g., in comparison to the acoustic cavity of a conventional LCRF or other acoustic resonator device, so that the aggregate thickness of the acoustic stack is a multiple of half the wavelength λ (or λ/2) corresponding to the thickness extensional resonance frequency of the LCRF device 200A. In the depicted embodiment, the composite bottom electrode 210′ has a thickness of approximately λ/2, and a combination of the piezoelectric layer 230 and the top electrode 240 has a thickness of approximately λ/2, so that the aggregate thickness of the acoustic stack of the LCRF device 200A is λ. Further, each of the first and second bottom electrode layers 211 and 212 may be approximately half the aggregate wavelength thickness of the corresponding composite bottom electrode 210′. That is, each of the first and second bottom electrode layers 211 and 212 has a thickness of approximately λ/4, for example, although the respective thicknesses may vary to provide unique benefits for any particular situation or to meet application specific design requirements of various implementations, as would be apparent to one skilled in the art.

As stated above, the top electrode 240 includes the first top comb electrode 110 and the second top comb electrode 120, each of which is formed of a single layer of conductive material. The first top comb electrode 110 is a signal electrode to which an electrical signal is applied, and the second top comb electrode 120 is a floating electrode providing an output for the electrical signal. Therefore, as shown in FIG. 2A, the first top fingers 111 and 112 receive the input electrical signal, and the second top fingers 121 and 122 are floating. The top electrode 240 may be formed of one or more electrically conductive materials, such as various metals compatible with semiconductor processes, including tungsten (W), molybdenum (Mo), iridium (Ir), aluminum (Al), platinum (Pt), ruthenium (Ru), niobium (Nb), and/or hafnium (Hf), for example. Meanwhile, the composite bottom electrode 210′ is grounded (e.g., connected to a ground voltage). The electrically conductive materials that may form the electrodes that are not composite electrodes, as identified herein, are the same for the various disclosed embodiments, and therefore will not be repeated. Also, although not shown, a passivation layer may be present on top of top electrode 240 (and in each embodiment discussed herein) with thickness sufficient to insulate all layers of the acoustic stack from the environment, including protection from moisture, corrosives, contaminants, debris and the like.

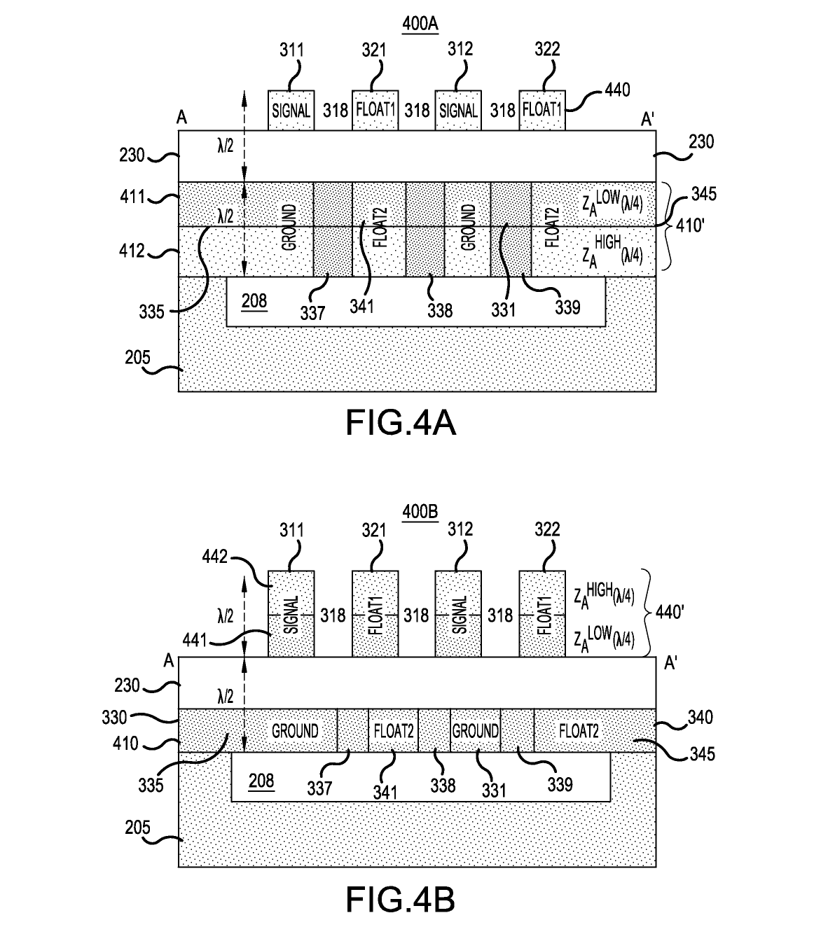

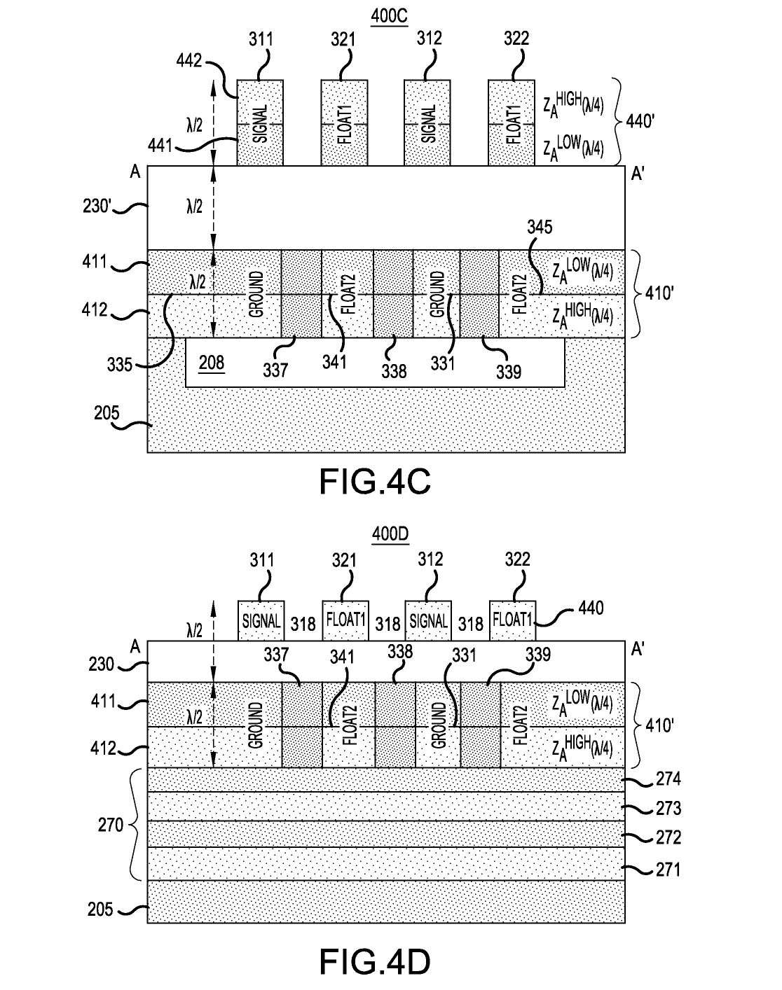

With regard to FIG. 2A (as well as FIGS. 4A, 6A and 9A, discussed herein), the approximately λ/2 thick composite bottom electrode 210′, formed of electrode layers having alternating low and high acoustic impedances (e.g., first bottom layer 211 and second bottom layer 212), substantially eliminates acoustic losses in the region where composite bottom electrode 210′, the piezoelectric layer 230 and the top electrode 240 overlaps the substrate 205, and enables higher electromechanical coupling coefficient kt² due to the presence of the top electrode 240, which may be made of high acoustic impedance material.

Referring to FIG. 2B, LCRF device 200B includes the substrate 205 defining the cavity 208 (e.g., air cavity), a bottom electrode 210 disposed on the substrate 205 over the cavity 208, the planarization layer 220 (optional) disposed adjacent to the bottom electrode 210 on the substrate 205, the piezoelectric layer 230 disposed over the bottom electrode 210 and the planarization layer 220, and a composite top electrode 240′ disposed on the piezoelectric layer 230. The bottom electrode 210, which is grounded, may be formed of material(s) having relatively high acoustic impedance (Z_{A}^{HIGH}), such as W, Ir or Mo, for example.

The composite top electrode 240′ includes the first top comb electrode 110 and the second top comb electrode 120, each of which is formed of two layers of conductive material in the present embodiment. That is, the composite top electrode 240′, in reference to proximity to the piezoelectric layer 230, includes first top electrode layer 241 adjacent the piezoelectric layer 230 and second top electrode layer 242 adjacent the first top electrode layer 241. Generally, the first top electrode layer 241 is formed of a material having a relatively low acoustic impedance (Z_{A}^{LOW}), such as Al, Ti or Be, while the second top electrode layer 242 is formed of a material having a relatively high acoustic impedance (Z_{A}^{HIGH}), such as W, Ir or Mo. Accordingly, the composite top electrode 240′ may function as an acoustic mirror, such as a DBR, as a practical matter. Notably, the second-harmonic resonance frequency of the acoustic stack comprising the bottom electrode 210, the piezoelectric layer 230 and the top electrode 240′ may be substantially similar to the first-harmonic resonance frequency of the acoustic stack comprising the bottom electrode 210 and piezoelectric layer 230. Such arrangement of resonance frequencies between metalized and gap regions may result in minimized acoustic scattering at the edges of the first and second fingers 111, 121, 112, and 122, and therefore suppress spurious resonances in the LCRF 200B electrical response resulting from the interleaving pattern of the first and second fingers 111, 121, 112, and 122. The first top comb electrode 110 is a signal electrode to which an electrical signal is applied, and the second top comb electrode 120 is a floating electrode providing an output for the electrical signal. Therefore, as shown in FIG. 2B, the first top fingers 111 and 112 of the composite top electrode 240′ receive the input electrical signal, and the second top fingers 121 and 122 are floating.

Collectively, the bottom electrode 210, the piezoelectric layer 230, and the composite top electrode 240′ constitute an acoustic stack of the LCRF device 200B. Also, overlapping portions of the bottom electrode 210, the piezoelectric layer 230, and the composite top electrode 240′ over the cavity 208 define a main membrane region of the LCRF device 200B, where the cavity 208 enables movement (or vibration) of the piezoelectric layer 230 in a vertical direction.

As discussed above with respect to the LCRF device 200A, the acoustic cavity of the LCRF device 200B is vertically extended, so that the aggregate thickness of the acoustic stack is a multiple of λ/2. In the depicted embodiment, the composite top electrode 240′ has a thickness of approximately λ/2, and a combination of the piezoelectric layer 230 and the bottom electrode 210 has a thickness of approximately λ/2, so that the aggregate thickness of the acoustic stack of the LCRF device 200B is λ. Further, each of the first and second top electrode layers 241 and 242 may have a thickness of approximately λ/4, for example, although the respective thicknesses may vary to provide unique benefits for any particular situation or to meet application specific design requirements of various implementations, as would be apparent to one skilled in the art.

With regard to FIG. 2B (as well as FIGS. 4B, 6B and 9B, discussed herein), the approximately λ/2 thick composite top electrode 240′, formed of electrode layers having alternating low and high acoustic impedances (e.g., first top electrode layer 241 and second top electrode layer 242), allows for acoustic morphing of the top electrode edge, as well as higher coupling coefficient kt² due to presence of bottom electrode 210, which may be made of high acoustic impedance material.

Referring to FIG. 2C, LCRF device 200C substantially combines the configurations of the single-ended LCRF devices 200A and 200B. That is, the LCRF device 200C has both the composite bottom electrode 210′ and the composite top electrode 240′, where the composite bottom electrode 210′ includes the first bottom electrode layer 211 adjacent piezoelectric layer 230′ and the second top electrode layer 212 adjacent the first bottom electrode layer 211, and the composite top electrode 240′ includes first top electrode layer 241 adjacent the piezoelectric layer 230′ and second top electrode layer 242 adjacent the first top electrode layer 241. In the depicted embodiment, the composite bottom electrode 210′ has a thickness of approximately λ/2, the composite top electrode 240′ has a thickness of approximately λ/2, and the piezoelectric layer 230′ also has a thickness of approximately λ/2 (making the piezoelectric layer 230′ approximately twice as thick as the piezoelectric layer 230 in the foregoing embodiments having only one composite electrode). Accordingly, the aggregate thickness of the acoustic stack of the LCRF device 200C is 3λ/2, which is appropriately a multiple of λ/2, as mentioned above.

With regard to FIG. 2C (as well as FIGS. 4C, 6C and 9C, discussed herein), the approximately λ/2 thick bottom electrode 210′ and top electrode 240′, each formed of electrode layers having alternating low acoustic impedance (e.g., first bottom and top electrode layers 211, 241) and high acoustic impedance (e.g., second bottom and top electrode layers 212, 242), effectively eliminate electrical series resistance Rs contributions. Also, the LCRF device 200C operates in the third harmonic, with the approximately λ/2 thick bottom and top electrodes 210′ and 240′, and the approximately λ/2 thick piezoelectric layer 230′, in which case the thickness of the piezoelectric layer 230′ may increase (e.g., to about 15500 Å for 3.6 GHz top/bottom ECR). This results in an increased area of the LCRF device 200C, and thus a lower perimeter-to-area loss and larger parallel resistance Rp. Further, since Normalized Peak Strain Energy (NPSE) distribution at the top surface of the piezoelectric layer 230′ is at null of the acoustic energy density, both in the active device and in the field region outside of the main membrane region, acoustic scattering at the edge of the top electrode 240′ may be largely eliminated. This leads to natural acoustic morphing (where the cut-off frequency is substantially the same inside and outside the main membrane region) of the LCRF device 200C, resulting in possibly improved insertion loss and suppressed spurious resonances outside of the passband of the LCRF device 200C. Also, the bottom electrode 210′ may prevent energy leakage to the substrate 205.

Referring to FIG. 2D, LCRF device 200D is substantially the same as LCRF device 200A, except that the acoustic reflector is implemented as an acoustic mirror, such as the representative Distributed Bragg Reflector (DBR) 270, as opposed to the cavity 208. In this configuration, the DBR 270 is disposed on the substrate 205, the composite bottom electrode 210′ is disposed on the DBR 270, the planarization layer 220 (optional) is disposed adjacent to the composite bottom electrode 210′ on the DBR 270, the piezoelectric layer 230 is disposed on the composite bottom electrode 210′ and the planarization layer 220, and the top electrode 240 is disposed over the piezoelectric layer 230. The LCRF device 200D is therefore effectively a solidly mounted LCRF device. Of course, the DBR 270 may likewise be substituted for the cavity 208 in the LCRF devices 200B and 200C, without departing from the scope of the present teachings.

The DBR 270 includes pairs of acoustic impedance layers formed of materials having different acoustic impedances, where the layer of material having the lower acoustic impedance is stacked on the layer of material having the higher acoustic impedance. For example, in the depicted embodiment, the DBR 270 includes stacked acoustic impedance layers 271, 272, 273 and 274, where the acoustic impedance layers 271 and 273 may be formed of a relatively high acoustic impedance material, such as tungsten (W) or molybdenum (Mo), and acoustic impedance layers 272 and 274 may be formed of a material having relatively low acoustic impedance, such as silicon oxide (SiOₓ), where x is an integer. Various illustrative fabrication techniques of acoustic mirrors are described by in U.S. Pat. No. 7,358,831 (Apr. 15, 2008), to Larson III, et al., which is hereby incorporated by reference in its entirety.

In the various embodiments depicted in FIGS. 2A-2B (as well as the embodiments addressed below), the substrate 205 may be formed of a material compatible with semiconductor processes, such as silicon (Si), gallium arsenide (GaAs), indium phosphide (InP), glass, sapphire, alumina, or the like, for example. The cavity 208 may be formed by etching a cavity in the substrate 205 and filling the etched cavity with a sacrificial material, such as PSG, for example, which is subsequently removed to leave an air space. Various illustrative fabrication techniques for an air cavity in a substrate are described by U.S. Pat. No. 7,345,410 (Mar. 18, 2008), to Grannen et al., which is hereby incorporated by reference in its entirety.

The piezoelectric layers 230, 230′ may be formed of any piezoelectric material compatible with semiconductor processes, such as aluminum nitride (AlN), zinc oxide (ZnO), zirconate titanate (PZT), lithium tantalate (LiTaO₃), or lithium niobate (LiNbO₃), for example. Also, in various embodiments, the piezoelectric layers 230, 230′ may be “doped” with at least one rare earth element, such as scandium (Sc), yttrium (Y), lanthanum (La), or erbium (Er), for example, to increase the piezoelectric coupling coefficient e₃₃ in the piezoelectric layer 230, 230′, thereby off-setting at least a portion of degradation of the electromechanical coupling coefficient Kt² of the LCRF device. Examples of doping piezoelectric layers with one or more rare earth elements for improving electromechanical coupling coefficient Kt² are provided by U.S. patent application Ser. No. 13/662,425 (filed Oct. 27, 2012), to Bradley et al., and U.S. patent application Ser. No. 13/662,460 (filed Oct. 27, 2012), to Grannen et al., which are hereby incorporated by reference in their entireties. Of course, doping piezoelectric layers with one or more rare earth elements may be applied to any of various embodiments. The above description of the piezoelectric layer 230, 230′ equally applies to the other embodiments identified herein, and therefore will not be repeated.

The planarization layer 220 may be formed of non-etchable borosilicate glass (NEBSG), for example. The planarization layer 220 is not strictly required for the functioning of the LCRF devices 200A-200D, but its presence can confer various benefits. For instance, the presence of the planarization layer 220 tends to improve structural stability, may improve the quality of growth of subsequent layers, and may allow bottom electrode 210 to be formed without its edges extending beyond the cavity 208. Further examples of potential benefits of planarization and/or method of fabricating the same are presented in U.S. Patent Application Publication No. 2013/0106534 (published May 2, 2013) to Burak et al., and U.S. patent application Ser. No. 14/225,710 (filed Mar. 26, 2014) to Nikkel et al., which are hereby incorporated by reference in their entireties.

Of course, other materials may be incorporated into the above and other features of LCRF devices 200A-200D (as well as the other acoustic resonator and filter devices described herein) without departing from the scope of the present teachings.

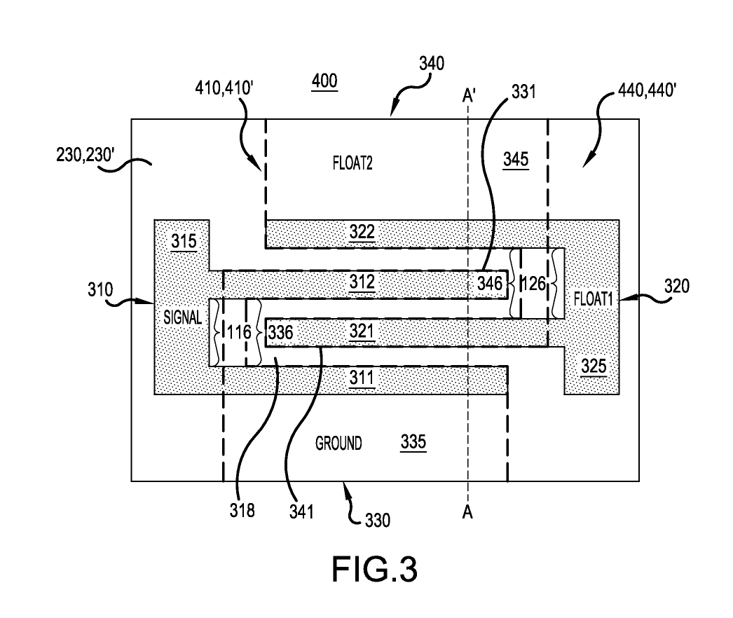

FIG. 3 is a top plan view of a LCRF device with at least one DBE, according to a representative embodiment, and FIGS. 4A-4D are cross-sectional views of the LCRF in FIG. 3 taken along a line A-A′ according to different embodiments. More particularly, FIG. 3 depicts LCRF device 400, which is a differential LRCF (as opposed a single-ended LCRF, discussed above). The cross-sectional views correspond to different variations of the differential LCRF device 400, respectively, as LCRF devices 400A-400D. The LCRF devices 400A-400D, which are acoustic resonators, have many of the same features, so a repetitive description of these features may be omitted in an effort to avoid redundancy.

Referring to FIG. 3, LCRF device 400 includes a top electrode 440 (or top contour electrode) comprising a first top comb electrode 310 and second top comb electrode 320. The first top comb electrode 310 includes a first top bus bar 315 and multiple representative first top fingers 311 and 312, separated by first space 316. The first top fingers 311 and 312 extend in a first direction from the first top bus bar 315. The second top comb electrode 320 similarly includes a second top bus bar 325 and multiple representative second top fingers 321 and 322, separated by second space 326. The second top fingers 321 and 322 extend in a second direction, opposite the first direction, from the second top bus bar 325. The first top comb electrode 310 is a signal electrode to which an electrical signal is applied, and the second top comb electrode 320 is a top (first) floating electrode providing an output for the electrical signal.

The top electrode 440 is interdigitated in that the first top finger 312 extends into the second space 326 between the second top fingers 321 and 322, and the second top finger 321 extends into the first space 316 between the first top fingers 311 and 312, creating top interleaving pattern of the LCRF device 400. The alternating first and second top fingers 311, 321, 312 and 322 are likewise separated by spaces or gaps 318, respectively. In the depicted embodiment, a top surface of a piezoelectric layer 230, 230′ is visible through the gaps 318.

The LCRF device 400 further includes a bottom electrode 410 (or bottom contour electrode) comprising a first bottom comb electrode 330 and second bottom comb electrode 340. The first bottom comb electrode 330 includes a first bottom bus bar 335 and at least one first bottom comb extension or first bottom comb-like finger, indicated by representative first bottom finger 331, which is separated from the first bottom bus bar 335 by first space 336. The first bottom finger 331 extends in a first direction away from the first top bus bar 315. The second bottom comb electrode 340 similarly includes a second bottom bus bar 345 and at least one second bottom comb extension or comb-like finger, indicated by representative second bottom finger 341, which is separated from the second bottom bus bar 345 by second space 346. The second bottom finger 341 extends in a second direction, opposite the first direction, away from the second top bus bar 325. The first bottom electrode 330 is a ground electrode connected to ground, and the second bottom electrode 340 is a bottom (second) floating electrode providing another output for the electrical signal. The bottom electrode 410 is likewise interdigitated in that the first bottom finger 331 extends into the second space 346, and the second bottom finger 341 extends into the first space 336, creating a bottom interleaving pattern of the LCRF device 400.

FIGS. 4A to 4D are cross-sectional diagrams, taken along line A-A′ of FIG. 3, illustrating LCRF devices, according to representative embodiments. Each of the LCRF devices shown in FIGS. 4A to 4D includes a bottom contour electrode having a bottom interleaving pattern, thus depicting a differential LCRF filter configuration.

Referring to FIG. 4A, LCRF device 400A includes substrate 205 defining a cavity 208 (e.g., air cavity), which serves as an acoustic reflector. The LCRF device 400A further includes composite bottom (contour) electrode 410′ disposed on the substrate 205 over the cavity 208, the piezoelectric layer 230 disposed on the bottom electrode 410′, and top (contour) electrode 440 disposed over the piezoelectric layer 230. (Although not shown, a planarization layer may be included adjacent the bottom electrode 410, as needed, in this and the other embodiments.)

The composite bottom electrode 410′ comprises (at least) two layers formed of different metal materials. More particularly, the composite bottom electrode 410′ includes first bottom electrode layer 411 adjacent the piezoelectric layer 230 and second bottom electrode layer 412 adjacent the first bottom electrode layer 411. As discussed above, the first bottom electrode layer 411 is formed of a material having a relatively low acoustic impedance (Z_{A}^{LOW}), while the second bottom electrode layer 412 is formed of a material having a relatively high acoustic impedance (Z_{A}^{HIGH}). Accordingly, the composite bottom electrode 410′ may function as an acoustic mirror, such as a DBR, as a practical matter, preventing residual energy confined in the bottom electrode 410′ from leaking into the substrate 205. Of course, the composite electrodes throughout the subject disclosure may comprise additional layers and/or different materials, in various embodiments, without departing from the scope of the present teachings.

Collectively, the composite bottom electrode 410′, the piezoelectric layer 230, and the top electrode 440 constitute an acoustic stack of the LCRF device 400A. Also, overlapping portions of the composite bottom electrode 410′, the piezoelectric layer 230, and the top electrode 440 over the cavity 208 define a main membrane region of the LCRF device 400A, where the cavity 208 enables movement (or vibration) of the piezoelectric layer 230 in a vertical direction.

As in the case of the LCRF devices 200A-200D, the acoustic cavity of each of the LCRF devices 400A-400D is vertically extended, so that the aggregate thickness of the acoustic stack is a multiple of half the wavelength λ (or λ/2) corresponding to the thickness extensional resonance frequency of the corresponding LCRF device 400A-400D. In the depicted embodiment, the composite bottom electrode 410′ has a thickness of approximately λ/2, and a combination of the piezoelectric layer 230 and the top electrode 440 has a thickness of approximately λ/2, so that the aggregate thickness of the acoustic stack of the LCRF device 400A is λ. Further, each of the first and second bottom electrode layers 411 and 412 may be approximately half the aggregate wavelength thickness of the corresponding composite bottom electrode 410′ (e.g., approximately λ/4), although the respective thicknesses of the first and second bottom electrode layers 411 and 412 may vary, as would be apparent to one skilled in the art.

The top electrode 440 includes the first top comb electrode 310 and the second top comb electrode 320, each of which is formed of a single layer of conductive material(s), exemplary compositions of which are as discussed above. The first top comb electrode 310 is a signal electrode to which an electrical signal is applied, and the second top comb electrode 320 is a first floating electrode providing an output for the electrical signal.

In addition, referring to the composite bottom electrode 410′, the first bottom comb electrode 330 is a ground electrode, and the second bottom comb electrode 340 is a second bottom floating electrode providing another output for the electrical signal. Therefore, as shown in FIG. 4A, the first top fingers 311 and 312 receive the input electrical signal, the second top fingers 321 and 322 and the second bottom finger 341 are floating, and the first bottom finger 331 is grounded. Notably, in the depicted embodiment, the spaces between the first and second bottom bus bars 335 and 345 and the first and second bottom fingers 331 and 341 of the composite bottom electrode 410′ are filled with a dielectric material (as opposed to being air spaces), such as NEBSG or non-conductive SiC, for example. These filled spaces include space 337 between the first bottom bus bar 335 and the second bottom finger 341, space 338 between the second bottom finger 341 and the first bottom finger 331, and space 339 between the first bottom finger 331 and the second bottom bus bar 345. The spaces 337-339 are at least partially aligned with the spaces 318 between the first top fingers 311, 312 and the second top fingers 321, 322, respectively. Also, the first bottom finger 331 is at least partially aligned with the first top finger 312, and the second bottom finger 341 is at least partially aligned with the second top finger 321. However, the relative placements of the bottom spaces 337-339 and the top spaces 318, as well as the relative placements the first and second bottom fingers 331, 341 and the first and second top fingers 311, 312, 321, 322, may vary without departing from the scope of the present teachings.

Referring to FIG. 4B, LCRF device 400B includes the substrate 205 defining the cavity 208, bottom electrode 410 disposed on the substrate 205 over the cavity 208, the piezoelectric layer 230 disposed over the bottom electrode 410, and composite top electrode 440′ disposed on the piezoelectric layer 230.

The composite top electrode 440′ comprises (at least) two layers formed of different metal materials. More particularly, the composite top electrode 440′ includes first top electrode layer 441 adjacent the piezoelectric layer 230 and second top electrode layer 442 adjacent the first bottom electrode layer 441. As discussed above, the first top electrode layer 441 is formed of a material having a relatively low acoustic impedance (Z_{A}^{LOW}), while the second top electrode layer 442 is formed of a material having a relatively high acoustic impedance (Z_{A}^{HIGH}). Accordingly, the composite top electrode 440′ may function as an acoustic mirror, such as a DBR, as a practical matter. Notably, the second-harmonic resonance frequency of the acoustic stack comprising the bottom electrode 340, the piezoelectric layer 230 and the top electrode 440′ may be substantially similar to the first-harmonic resonance frequency of the acoustic stack comprising spaces 337 through 339 and the piezoelectric layer 230. Such arrangement of resonance frequencies between metalized and gap regions may result in minimized acoustic scattering at the edges of first and second fingers 311, 321, 312 and 322 and therefore suppress spurious resonances in the LCRF device 400B electrical response resulting from the interleaving pattern of the first and second fingers 311, 321, 312 and 322. The bottom electrode 410 may be formed of material(s) having a relatively high acoustic impedance (Z_{A}^{HIGH}), such as W, Ir or Mo, for example.

Collectively, the composite top electrode 440′, the piezoelectric layer 230, and the bottom electrode 410 constitute an acoustic stack of the LCRF device 400B. Also, overlapping portions of the composite top electrode 440′, the piezoelectric layer 230, and the bottom electrode 410 over the cavity 208 define a main membrane region of the LCRF device 400B, where the cavity 208 enables movement (or vibration) of the piezoelectric layer 230 in a vertical direction.

In the depicted embodiment, the composite top electrode 440′ has a thickness of approximately λ/2, and a combination of the piezoelectric layer 230 and the bottom electrode 410 has a thickness of approximately λ/2, so that the aggregate thickness of the acoustic stack of the LRCF device 400A is λ. Further, each of the first and second top electrode layers 441 and 442 may be approximately half the aggregate wavelength thickness of the corresponding composite top electrode 440′ (e.g., approximately λ/4), although the respective thicknesses of the first and second top electrode layers 441 and 442 may vary, as would be apparent to one skilled in the art. In addition, referring to the composite top electrode 440′, the first top comb electrode 310 is a signal electrode, and the second top comb electrode 320 is a top (first) floating electrode providing another output for the electrical signal.

The bottom electrode 410 includes the first bottom comb electrode 330 and the second bottom comb electrode 340, each of which is formed of a single layer of conductive material(s), exemplary compositions of which are as discussed above. The first bottom comb electrode 310 is a ground electrode connected to ground, and the second bottom comb electrode 340 is bottom (second) floating electrode providing another output for the electrical signal. Therefore, as shown in FIG. 4A, the first top fingers 311 and 312 receive the input electrical signal, the second top fingers 321 and 322 and the second bottom finger 341 are floating, and the first bottom finger 331 is grounded. Again, in the depicted embodiment, the spaces between the first and second bottom bus bars 335 and 345 and the first and second bottom fingers 331 and 341 of the bottom electrode 410 are filled with a dielectric material. These filled spaces include space 337 between the first bottom bus bar 335 and the second bottom finger 341, space 338 between the second bottom finger 341 and the first bottom finger 331, and space 339 between the first bottom finger 331 and the second bottom bus bar 345, as discussed above.

Referring to FIG. 4C, LCRF device 400C substantially combines the configurations of the differential LCRF devices 400A and 400B. That is, the LCRF device 400C includes both the composite bottom electrode 410′ and the composite top electrode 440′. The composite bottom electrode 410′ includes the first bottom electrode layer 411 adjacent piezoelectric layer 230′ and the second bottom electrode layer 412 adjacent the first bottom electrode layer 411, and the composite top electrode 440′ includes first top electrode layer 441 adjacent the piezoelectric layer 230′ and second top electrode layer 442 adjacent the first top electrode layer 441. In the depicted embodiment, the composite bottom electrode 410′ has a thickness of approximately λ/2, the composite top electrode 440′ has a thickness of approximately λ/2, and the piezoelectric layer 230′ also has a thickness of approximately λ/2. Accordingly, the aggregate thickness of the acoustic stack of the LCRF device 400C is 3λ/2.

Referring to FIG. 4D, LCRF device 400D is substantially the same as LCRF device 400A, except that the acoustic reflector is implemented as an acoustic mirror, such as the representative DBR 270, as opposed to the cavity 208. In this configuration, the DBR 270 is disposed on the substrate 205, the composite bottom electrode 410′ is disposed on the DBR 270, the piezoelectric layer 230 is disposed on the composite bottom electrode 410′, and the top electrode 440 is disposed over the piezoelectric layer 230. Of course, the DBR 270 may likewise be substituted for the cavity 208 in the LCRF device 400B and the LCRF device 400C, without departing from the scope of the present teachings.

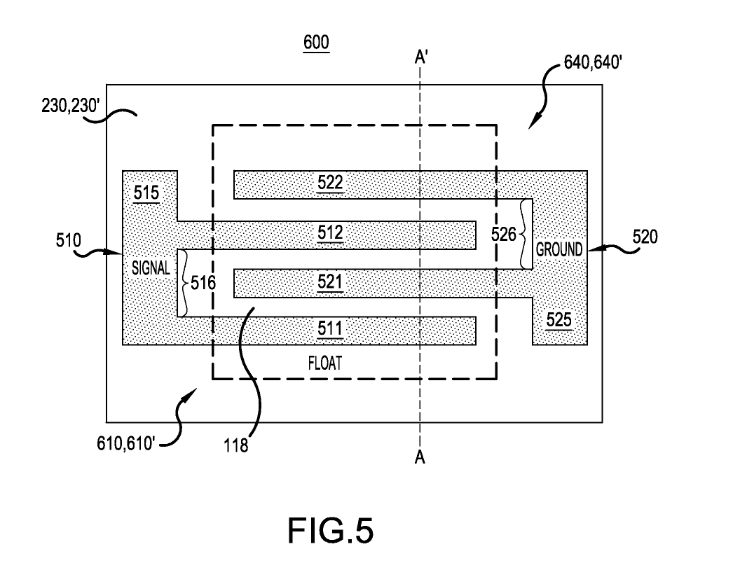

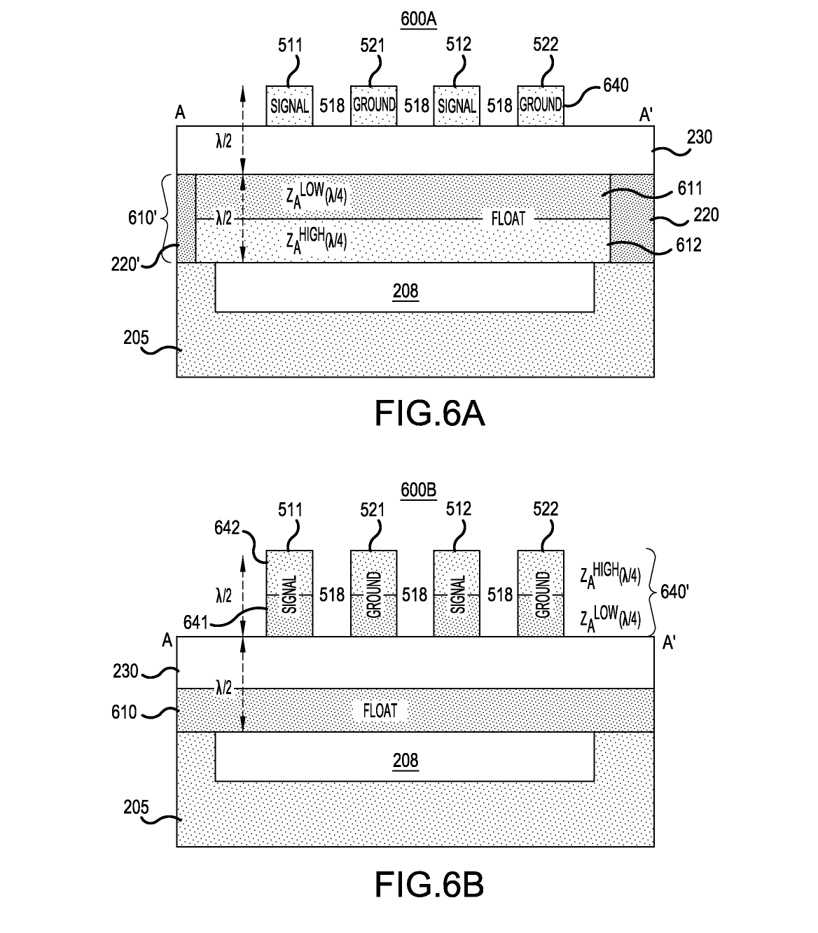

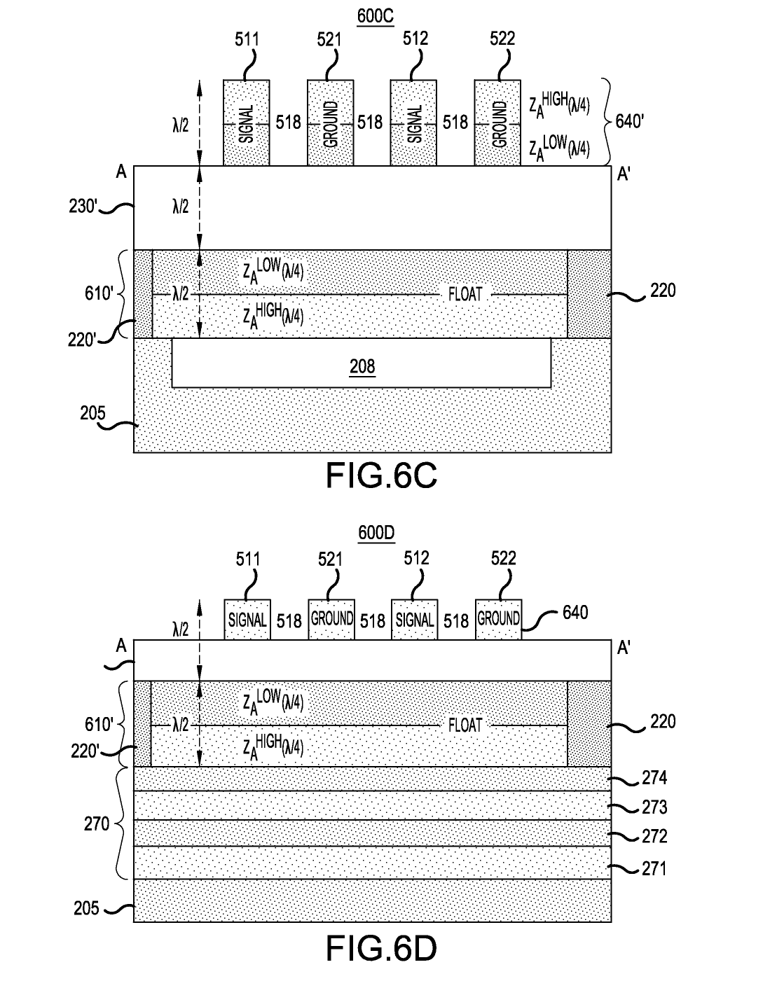

FIG. 5 is a top plan view of a lateral-field-excitation (LFE) contour mode resonator (CMR) device with DBEs, according to a representative embodiment, and FIGS. 6A-6D are cross-sectional views of the LFE-CMR device in FIG. 5 taken along a line A-A′ according to different embodiments. More particularly, the cross-sectional views correspond to different variations of the LFE-CMR device 600, respectively, as LFE-CMR devices 600A-600D. The LFE-CMR devices 600A-600D, which are acoustic resonators, have many of the same features, so a repetitive description of these features may be omitted in an effort to avoid redundancy.

Referring to FIG. 5, LFE-CMR device 600 includes a top electrode 640, which may be referred to as a contour electrode, comprising a first top comb electrode 510 and second top comb electrode 520. The first top comb electrode 510 includes a first top bus bar 515 and multiple first top comb extensions or first top comb-like fingers, indicated by representative first top fingers 511 and 512, separated by first space 516. The first top fingers 511 and 512 extend in a first direction from the first top bus bar 515. The second top comb electrode 520 similarly includes a second top bus bar 525 and multiple second top comb extensions or top comb-like fingers, indicated by representative second top fingers 521 and 522, separated by second space 526. The second top fingers 521 and 522 extend in a second direction, opposite the first direction, from the second top bus bar 525. In the depicted embodiment, the first top comb electrode 510 is a signal electrode to which an electrical signal is applied, and the second top comb electrode 520 is a ground electrode (as opposed to a floating electrode, as discussed above with reference to second top comb electrodes in FIGS. 1-4D) connected to ground.

The top electrode 640 is interdigitated in that the first top finger 512 of the first top comb electrode 510 extends into the second space 526 between the second top fingers 521 and 522 of the second top comb electrode 520, and the second top finger 521 of the second top comb electrode 520 extends into the first space 516 between the first top fingers 511 and 512 of the first top comb electrode 510. This arrangement forms a top interleaving pattern. The alternating first and second top fingers 511, 521, 512, and 522 are likewise separated by spaces or gaps 518, respectively. The top surface of the piezoelectric layer 230, 230′ is visible through the gaps 518.

Referring to FIG. 6A, LFE-CMR device 600A with DBEs includes the substrate 205 defining the cavity 208, a composite bottom electrode 610′ disposed on the substrate 205 over the cavity 208, a planarization layer 220 (optional) disposed adjacent to the composite bottom electrode 610′ on the substrate 205, piezoelectric layer 230 disposed on the composite bottom electrode 610′ and the planarization layer 220, 220′ (optional), and a top (contour) electrode 640 disposed over the piezoelectric layer 230.

The composite bottom electrode 610′ comprises (at least) two layers formed of different metal materials. More particularly, the composite bottom electrode 610′ includes first bottom electrode layer 611 adjacent the piezoelectric layer 230 and second bottom electrode layer 612 adjacent the first bottom electrode layer 611. As discussed above, the first bottom electrode layer 611 is formed of a material having a relatively low acoustic impedance (Z_{A}^{LOW}), while the second bottom electrode layer 612 is formed of a material having a relatively high acoustic impedance (Z_{A}^{HIGH}). Accordingly, the composite bottom electrode 610′ may function as an acoustic mirror, such as a DBR, as a practical matter, preventing residual amounts of acoustic energy confined in the bottom electrode 610′ from leaking into the substrate 205.

Collectively, the composite bottom electrode 610′, the piezoelectric layer 230, and the top electrode 640 constitute an acoustic stack of the LFE-CMR device 600A. Also, overlapping portions of the composite bottom electrode 610′, the piezoelectric layer 230, and the top electrode 640 over the cavity 208 define a main membrane region of the LFE-CMR device 600A, where the cavity 208 enables movement (or vibration) of the piezoelectric layer 230 in a vertical direction.

As in the case of the LCRF devices 200A-200D, the acoustic cavity of each of the LFE-CMR devices 600A-600D is vertically extended, so that the aggregate thickness of the acoustic stack is a multiple of half the wavelength λ (or λ/2) corresponding to the thickness extensional resonance frequency of the corresponding LFE-CMR device 600A-600D. In the depicted embodiment, the composite bottom electrode 610′ has a thickness of approximately λ/2, and a combination of the piezoelectric layer 230 and the top electrode 640 has a thickness of approximately λ/2, so that the aggregate thickness of the acoustic stack of the LFE-CMR 600A is λ. Further, each of the first and second bottom electrode layers 611 and 612 may be approximately half the aggregate wavelength thickness of the corresponding composite bottom electrode 610′ (e.g., approximately λ/4), although the respective thicknesses of the first and second bottom electrode layers 611 and 612 may vary, as would be apparent to one skilled in the art.

As stated above, the first top comb electrode 510 is a signal electrode to which an electrical signal is applied, and the second top comb electrode 520 is a ground electrode connected to ground. Therefore, as shown, the first top fingers 511 and 512 receive the input electrical signal, and the second top fingers 521 and 522 are grounded. Meanwhile, the composite bottom electrode 610′ is floating. (Because it is floating, the composite bottom electrode 610′ may be described simply as a conductive or metal layer, but for the sake of simplifying description, the floating bottom electrode 610′ will continue to be referred to as an electrode when configured in a floating condition.) As a result, application of the electrical signal to the first top fingers 511 and 512 excites mechanical motion (i.e., predominantly lateral-field-excitation) in the piezoelectric layer 230 resulting both from lateral electric field between the first top fingers 511 and 512 and the grounded second top fingers 521 and 522, as well as from vertical electric field between the first top fingers 511 and 512, the floating bottom electrode 610′, and the grounded second top fingers 521 and 522.

Referring to FIG. 6B, LFE-CMR device 600B includes the substrate 205 defining the cavity 208, bottom electrode 610 disposed on the substrate 205 over the cavity 208, the piezoelectric layer 230 disposed over the bottom electrode 610, and composite top electrode 640′ disposed on the piezoelectric layer 230. (Although not shown, a planarization layer may be included adjacent the bottom electrode 610, as needed, in this and the other embodiments.)

The composite top electrode 640′ comprises (at least) two layers formed of different metal materials. More particularly, the composite top electrode 640′ includes first top electrode layer 641 adjacent the piezoelectric layer 230 and second top electrode layer 642 adjacent the first bottom electrode layer 641. As discussed above, the first top electrode layer 641 is formed of a material having a relatively low acoustic impedance (Z_{A}^{LOW}), while the second top electrode layer 642 is formed of material(s) having a relatively high acoustic impedance (Z_{A}^{HIGH}). Accordingly, the composite top electrode 640′ may function as an acoustic mirror, such as a DBR, as a practical matter. Notably, the second-harmonic resonance frequency of the acoustic stack comprising the bottom electrode 640, the piezoelectric layer 230 and the composite top electrode 640′ may be substantially similar to the first-harmonic resonance frequency of the acoustic stack comprising the bottom electrode 610 and piezoelectric layer 230. Such an arrangement of resonance frequencies between metalized and gap regions may result in minimized acoustic scattering at the edges of first and second fingers 511, 521, 512 and 522, and therefore suppress spurious resonances in the LFE-CMR device 600B electrical response resulting from the interleaving patterns of the first and second fingers 511, 521, 512 and 522. The bottom electrode 610, which is floating, may be formed of a material having a relatively high acoustic impedance (Z_{A}^{HIGH}), such as W, Ir or Mo, for example.

Collectively, the composite top electrode 640′, the piezoelectric layer 230, and the bottom electrode 610 constitute an acoustic stack of the LFE-CMR device 600B. Also, overlapping portions of the composite top electrode 640′, the piezoelectric layer 230, and the bottom electrode 610 over the cavity 208 define a main membrane region of the LFE-CMR device 600B, where the cavity 208 enables movement (or vibration) of the piezoelectric layer 230 in a vertical direction.

In the depicted embodiment, the composite top electrode 640′ has a thickness of approximately λ/2, and a combination of the piezoelectric layer 230 and the bottom electrode 610 has a thickness of approximately λ/2, so that the aggregate thickness of the acoustic stack of the LCRF device 600A is λ. Further, each of the first and second top electrode layers 641 and 642 may be approximately half the aggregate wavelength thickness of the corresponding composite top electrode 640′ (e.g., approximately λ/4), although the respective thicknesses of the first and second top electrode layers 641 and 642 may vary, as would be apparent to one skilled in the art.

In addition, referring to the composite top electrode 640′, the first top comb electrode 510 is a signal electrode to which an electrical signal is applied, and the second top comb electrode 520 is a ground electrode. Therefore, as shown, the first top fingers 511 and 512 receive the input electrical signal, and the second top fingers 521 and 522 are grounded. Meanwhile, the bottom electrode 610 is grounded, and may be formed of one or more electrically conductive materials, such as various metals compatible with semiconductor processes, including W, Mo, Ir, Al, Pt, Ru, Nb, and/or Hf, for example, as discussed above. (Because it is floating, the composite bottom electrode 610′ may be described simply as a conductive or metal layer, but for the sake of simplifying description, the floating bottom electrode 610 will continue to be referred to as an electrode when configured in a floating condition.) As a result, application of the electrical signal to the first top fingers 511 and 512 excites mechanical motion in the piezoelectric layer 230 resulting both from lateral electric field between the first top fingers 511 and 512 and the grounded second top fingers 521 and 522, as well as from vertical electric field between the first top fingers 511 and 512, the floating bottom electrode 610, and the grounded second top fingers 521 and 522.

Referring to FIG. 6C, LFE-CMR device 600C substantially combines the configurations of the single-ended LCRF devices 600A and 600B. That is, the LFE-CMR device 600C has both the composite bottom electrode 610′ and the composite top electrode 640′, where the composite bottom electrode 610′ includes the first bottom electrode layer 611 adjacent piezoelectric layer 230′ and the second top electrode layer 612 adjacent the first bottom electrode layer 611, and the composite top electrode 640′ includes first top electrode layer 641 adjacent the piezoelectric layer 230′ and second top electrode layer 642 adjacent the first top electrode layer 641. In the depicted embodiment, the composite bottom electrode 610′ has a thickness of approximately λ/2, the composite top electrode 640′ has a thickness of approximately λ/2, and the piezoelectric layer 230′ also has a thickness of approximately λ/2 (making the piezoelectric layer 230′ approximately twice as thick as the piezoelectric layer 230 in the foregoing embodiments having only one composite electrode). Accordingly, the aggregate thickness of the LFE-CMR device 600C is 3λ/2.

Referring to FIG. 6D, LFE-CMR device 600D is substantially the same as LFE-CMR device 600A, except that the acoustic reflector is implemented as an acoustic mirror, such as the representative DBR 270, as opposed to the cavity 208. In this configuration, the DBR 270 is disposed on the substrate 205, the composite bottom electrode 610′ is disposed on the DBR 270, the planarization layer 220, 220′ (optional) is disposed adjacent to the composite bottom electrode 610′ on the DBR 270, the piezoelectric layer 230 is disposed on the composite bottom electrode 610′ and the planarization layer 220, 220, and the top electrode 640 is disposed over the piezoelectric layer 230. The LFE-CMR device 600D is therefore effectively a solidly mounted LFE-CMR device. Of course, the DBR 270 may likewise be substituted for the cavity 208 in the LFE-CMR devices 600B and 600C, without departing from the scope of the present teachings.

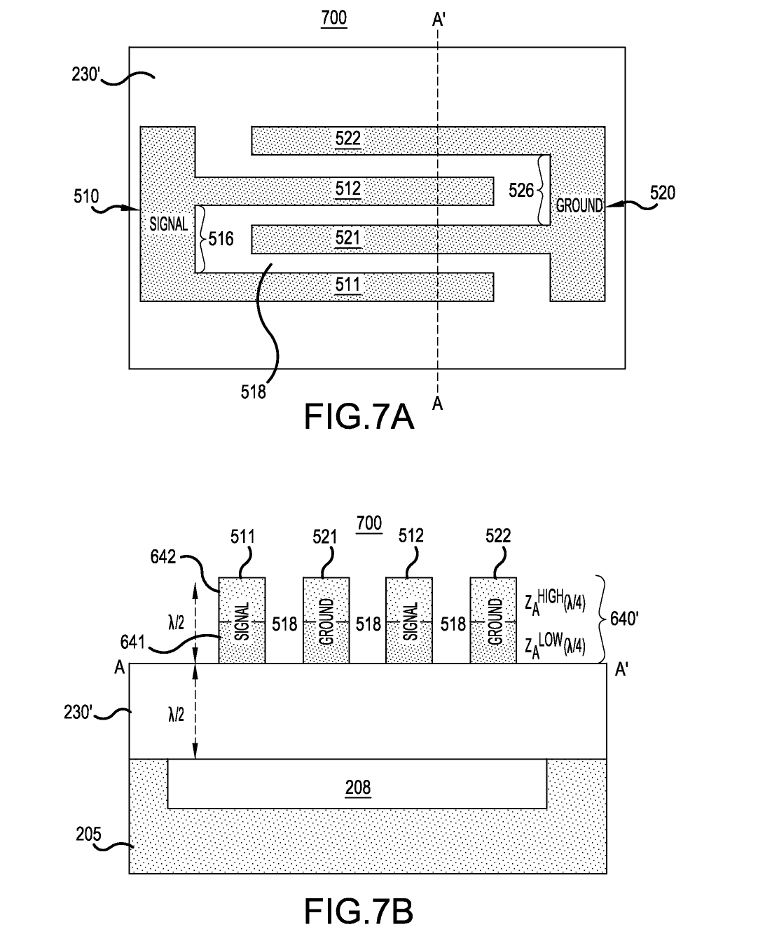

FIG. 7A is a top plan view of a lateral-field-excitation (LFE) contour mode resonator (CMR) device with DBEs and without bottom metal, according to a representative embodiment. FIG. 7B is a cross-sectional view of the LFE-CMR device in FIG. 7A taken along a line A-A′, according to the representative embodiment.

Referring to FIGS. 7A and 7B, LFE-CMR device 700, which is an acoustic resonator, includes composite top electrode 640′ comprising first top comb electrode 510 and second top comb electrode 520. The first top comb electrode 510 includes the first top bus bar 515 and multiple representative first top fingers 511 and 512 separated by first space 516. The first top fingers 511 and 512 extend in a first direction from the first top bus bar 515. The second top comb electrode 520 similarly includes second top bus bar 525 and multiple representative second top fingers 521 and 522 separated by second space 526. The second top fingers 521 and 522 extend in a second direction, opposite the first direction, from the second top bus bar 525. The first top comb electrode 510 is a signal electrode to which an electrical signal is applied, and the second top comb electrode 520 is a ground electrode. The composite top electrode 640′ is interdigitated, creating an interleaving pattern, as discussed above.

The LFE-CMR device 700 includes the substrate 205 defining the cavity 208, the piezoelectric layer 230′ disposed on the substrate 205 over the cavity 208, and the composite top (contour) electrode 640′ disposed on the piezoelectric layer 230′. In an alternative embodiment, the cavity 208 may be replaced by an acoustic mirror, such as the DBR 270, to provide an acoustic resonator, without departing from the scope of the present teachings. The composite top electrode 640′ includes first top electrode layer 641 adjacent the piezoelectric layer 230′ and second top electrode layer 642 adjacent the first top electrode layer 641. In the depicted embodiment, the composite top electrode 640′ has a thickness of approximately λ/2, and the piezoelectric layer 230′ also has a thickness of approximately λ/2. Accordingly, the aggregate thickness of the LFE-CMR device 700 is λ.

As mentioned above, the LFE-CMR device 700 includes no bottom metal, so there is no bottom electrode 610, 610′, for example. As a result of this configuration (e.g., no floating bottom electrode 610, 610′ or other metal layer between the piezoelectric layer 230′ and the substrate 205, application of the electrical signal to the first top fingers 511 and 512 excites the piezoelectric layer 230′ through lateral coupling, thus effectively resembling a SAW resonator. Notably, the presence of the cavity 208 prevents a pure surface wave from existing in the LFE-CMR device 700. Instead, two Lamb modes exist, one with peak energy confined to the top surface of the piezoelectric layer 230′ and the other one with the peak energy confined to the bottom surface of the piezoelectric layer 230′. In LFE-CMR device 700 the lateral electric field predominantly excites the Lamb mode with peak energy confined to the top surface of piezoelectric layer 230′ at frequencies close to the series resonance frequency Fs. However, some residual excitation of the Lamb mode with peak energy confined to the bottom surface of piezoelectric layer 230 through the fringing electric field also may be possible.

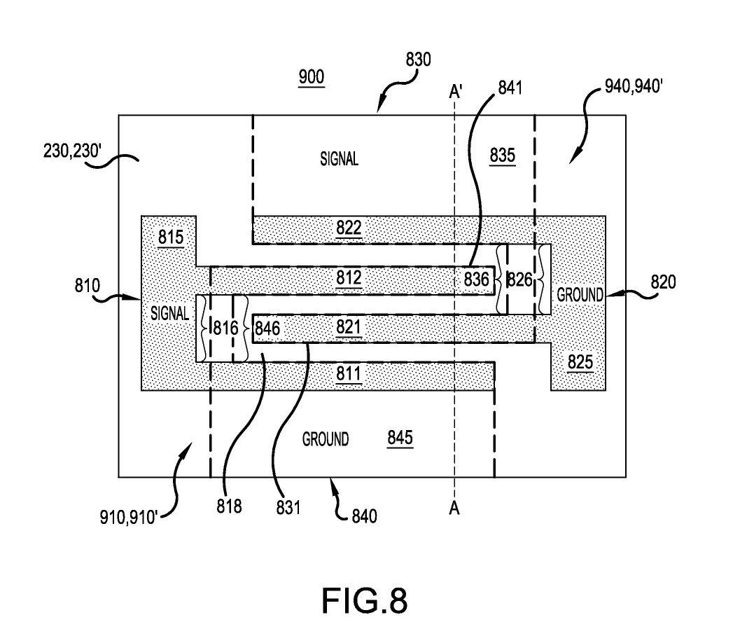

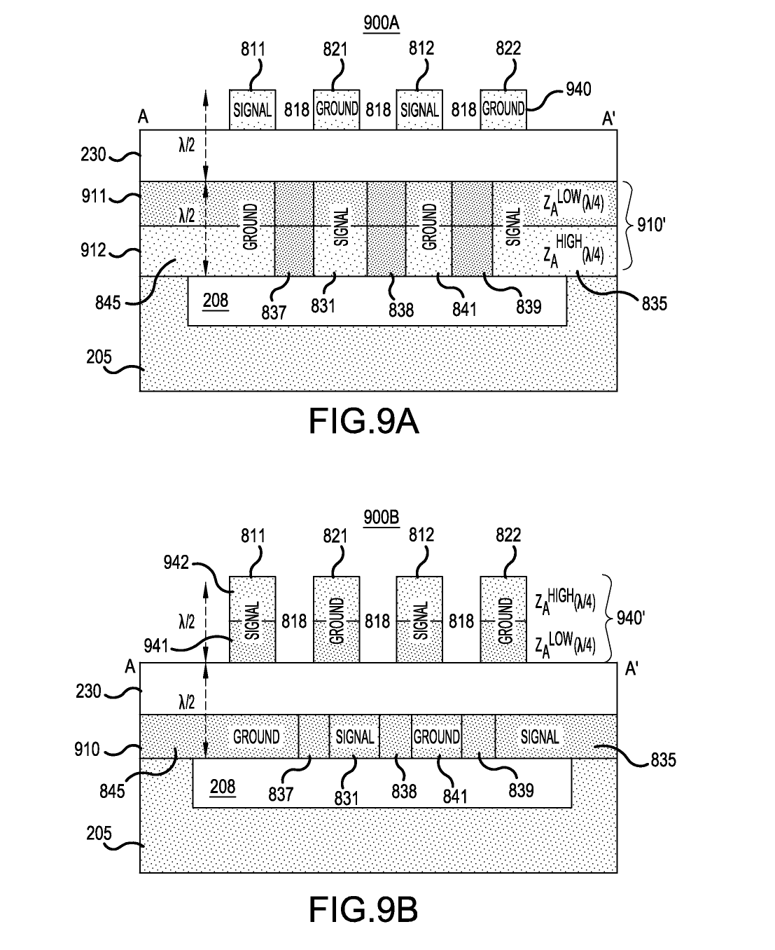

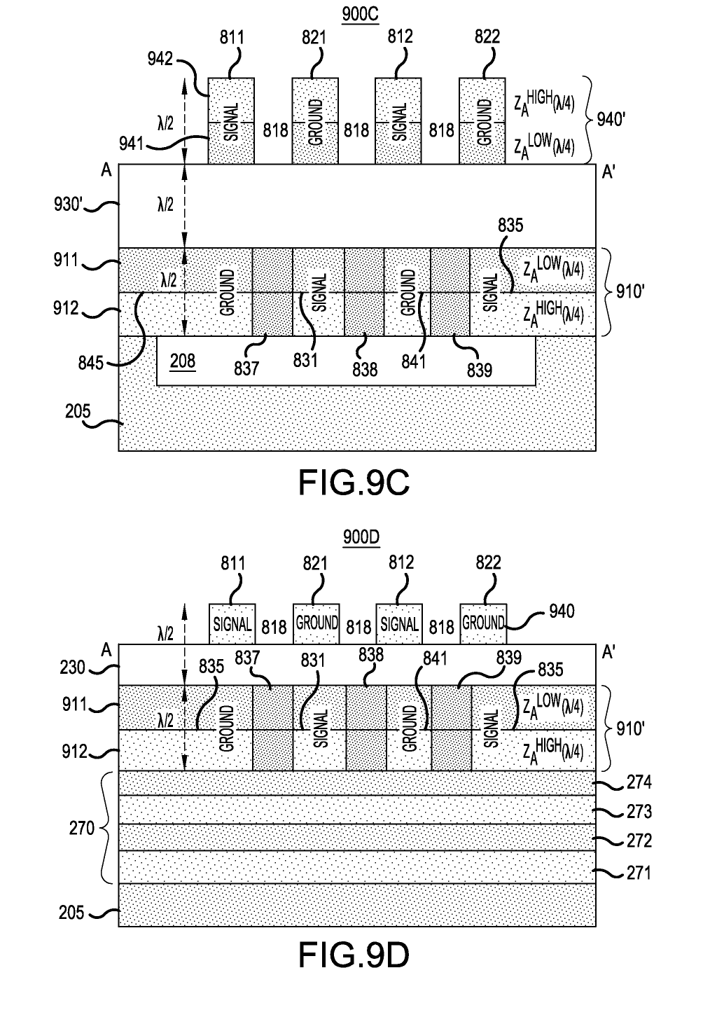

FIG. 8 is a top plan view of a thickness-field-excitation (TFE) contour mode resonator (CMR) device with DBEs, according to a representative embodiment, and FIGS. 9A-9D are cross-sectional views of the TFE-CMR device in FIG. 8 taken along a line A-A′ according to different embodiments. More particularly, the cross-sectional views correspond to different variations of the TFE-CMR device 900, respectively. The TFE-CMR devices 900A-900D, which are acoustic resonators, have many of the same features, so a repetitive description of these features may be omitted in an effort to avoid redundancy.

Referring to FIG. 8, TFE-CMR device 900 includes a top electrode 940, 940′ (or top contour electrode) comprising a first top comb electrode 810 and second top comb electrode 820. The first top comb electrode 810 includes a first top bus bar 815 and multiple representative first top fingers 811 and 812, separated by first space 816. The first top fingers 811 and 812 extend in a first direction from the first top bus bar 815. The second top comb electrode 820 similarly includes a second top bus bar 825 and multiple representative second top fingers 821 and 822, separated by second space 826. The second top fingers 821 and 822 extend in a second direction, opposite the first direction, from the second top bus bar 825. The first top comb electrode 810 is a top signal electrode to which an electrical signal is applied, and the second top comb electrode 820 is a top ground electrode connected to ground. The top electrode 840, 840′ is interdigitated in that the first top finger 812 extends into the second space 826 between the second top fingers 821 and 822, and the second top finger 821 extend into the first space 816 between the first top fingers 811 and 812, creating top interleaving pattern. The alternating first and second top fingers 811, 821, 812 and 822 are likewise separated by spaces or gaps 818, respectively.

The TFE-CMR device 900 further includes a bottom electrode 910, 910′ (or bottom contour electrode) comprising a first bottom comb electrode 830 and second bottom comb electrode 840. The first bottom comb electrode 830 includes a first bottom bus bar 835 and at least one representative first bottom finger 831, which is separated from the first bottom bus bar 835 by first space 836. The first bottom finger 831 extends in the first direction away from the second top bus bar 825. The second bottom comb electrode 840 similarly includes a second bottom bus bar 845 and at least one representative second bottom finger 841, which is separated from the second bottom bus bar 845 by second space 846. The second bottom finger 841 extends in the first direction, opposite the second direction, away from the first top bus bar 815. The first bottom comb electrode 830 is a bottom signal electrode, and the second bottom comb electrode 840 is a bottom ground electrode connected to ground. The bottom electrode 910, 910′ is likewise interdigitated in that the first bottom finger 831 extends into the second space 846, and the second bottom finger 841 extends into the first space 836, creating a bottom interleaving pattern.

FIGS. 9A to 9D are cross-sectional diagrams, taken along line A-A′ of FIG. 8, illustrating TFE-CMR devices with DBEs, according to representative embodiments. Each of the TFE-CMR devices shown in FIGS. 9A to 9D includes a bottom contour electrode having a bottom interleaving pattern, thereby enabling thickness-field-excitation.

Referring to FIG. 9A, TFE-CMR device 900A includes substrate 205 defining a cavity 208, a composite bottom (contour) electrode 910′ disposed on the substrate 205 over the cavity 208, a piezoelectric layer 230 disposed on the composite bottom electrode 910′, and a top electrode layer 940 disposed on the piezoelectric layer 230. (Although not shown, a planarization layer may be included adjacent the bottom electrode 910′, as needed, in this and the other embodiments.)

The composite bottom electrode 910′ comprises (at least) two layers formed of different metal materials. More particularly, the composite bottom electrode 910′ includes first bottom electrode layer 911 adjacent the piezoelectric layer 230 and second bottom electrode layer 912 adjacent the first bottom electrode layer 911. As discussed above, the first bottom electrode layer 911 is formed of a material having a relatively low acoustic impedance (Z_{A}^{LOW}), while the second bottom electrode layer 912 is formed of a material having a relatively high acoustic impedance (Z_{A}^{HIGH}). Accordingly, the composite bottom electrode 910′ may function as an acoustic mirror, such as a DBR, as a practical matter, preventing residual amounts of energy confined in the bottom electrode 910′ from leaking into the substrate 205. Of course, the composite electrodes throughout the subject disclosure may comprise additional layers and/or different materials, in various embodiments, without departing from the scope of the present teachings.

Collectively, the composite bottom electrode 910′, the piezoelectric layer 230, and the top electrode 940 constitute an acoustic stack of the TFE-CMR device 900A. Also, overlapping portions of the composite bottom electrode 910′, the piezoelectric layer 230, and the top electrode 940 over the cavity 208 define a main membrane region of the TFE-CMR device 900A, where the cavity 208 enables movement (or vibration) of the piezoelectric layer 230 in a vertical direction.

As in the case of the LCRF devices 200A-200D, the acoustic cavity of each of the TFE-CMR devices 900A-900D is vertically extended, so that the aggregate thickness of the acoustic stack is a multiple of half the wavelength λ (or λ/2) corresponding to the thickness extensional resonance frequency of the corresponding TFE-CMR device 900A-900D. In the depicted embodiment, the composite bottom electrode 910′ has a thickness of approximately λ/2, and a combination of the piezoelectric layer 230 and the top electrode 940 has a thickness of approximately λ/2, so that the aggregate thickness of the acoustic stack of the TFE-CMR device 900A is λ. Further, each of the first and second bottom electrode layers 911 and 912 may be approximately half the aggregate wavelength thickness of the corresponding composite bottom electrode 910′ (e.g., approximately λ/4), although the respective thicknesses of the first and second bottom electrode layers 911 and 912 may vary, as would be apparent to one skilled in the art.

As stated above, the first top comb electrode 810 is a top signal electrode to which an electrical signal is applied, and the second top comb electrode 820 is a top ground electrode. In addition, the first bottom comb electrode 830 is another signal electrode, and the second bottom comb electrode 840 is another ground electrode. Notably, in the depicted embodiment, the spaces between the first and second bottom bus bars 835 and 845 and the second and first bottom fingers 831 and 841 of the composite bottom electrode 910′ are respectively filled with a dielectric material (as opposed to being air spaces), such as NEBSG or non-conductive SiC, for example. These filled spaces include space 837 between the second bottom bus bar 845 and the first bottom finger 831, space 838 between the first and second bottom fingers 831 and 841, and space 839 between the second bottom finger 841 and the first bottom bus bar 835. The spaces 837-839 are at least partially aligned with the spaces 818 between the first top fingers 811, 812 and the second top fingers 821, 822, respectively. Also, the first bottom finger 831 is at least partially aligned with the second top finger 821, and the second bottom finger 841 is at least partially aligned with the first top finger 812. However, the relative placements of the bottom spaces 837-839 and the top spaces 818, as well as the relative placements the first and second bottom fingers 831, 841 and the first and second top fingers 811, 812, 821, 822, may vary without departing from the scope of the present teachings.

Referring to FIG. 9B, TFE-CMR device 900B includes the substrate 205 defining the cavity 208, the bottom electrode 910 disposed on the substrate 205 over the cavity 208, the piezoelectric layer 230 disposed on the bottom electrode 910, and a composite top electrode 940′ disposed on the piezoelectric layer 230.

The composite top electrode 940′ comprises (at least) two layers formed of different metal materials. More particularly, the composite top electrode 940′ includes first top electrode layer 941 adjacent the piezoelectric layer 230 and second top electrode layer 942 adjacent the first top electrode layer 941. As discussed above, the first top electrode layer 941 is formed of a material having a relatively low acoustic impedance (Z_{A}^{LOW}), while the second top electrode layer 942 is formed of a material having a relatively high acoustic impedance (Z_{A}^{HIGH}). Accordingly, the composite top electrode 940′ may function as an acoustic mirror, such as a DBR, as a practical matter. Notably, the second-harmonic resonance frequency of the acoustic stack comprising the bottom electrode 910, the piezoelectric layer 230 and the top electrode 940′ may be substantially similar to the first-harmonic resonance frequency of the acoustic stack comprising spaces 837 through 839 and piezoelectric layer 230. Such an arrangement of resonance frequencies between metalized and gap regions may result in minimized acoustic scattering at the edges of the first and second fingers 811, 821, 812 and 822, and therefore suppress spurious resonances in the TFE-CMR device 900B electrical response resulting from the interleaving pattern of the first and second fingers 811, 821, 812 and 822. The bottom electrode 910 may be formed of material(s) having a relatively high acoustic impedance (Z_{A}^{HIGH}).

Collectively, the composite top electrode 940′, the piezoelectric layer 230, and the bottom electrode 910 constitute an acoustic stack of the TFE-CMR device 900B. Also, overlapping portions of the composite top electrode 940′, the piezoelectric layer 230, and the bottom electrode 910 over the cavity 208 define a main membrane region of the TFE-CMR device 900B, where the cavity 208 enables movement (or vibration) of the piezoelectric layer 230 in a vertical direction.

In the depicted embodiment, the composite top electrode 940′ has a thickness of approximately λ/2, and a combination of the piezoelectric layer 230 and the bottom electrode 910 has a thickness of approximately λ/2, so that the aggregate thickness of the acoustic stack of the TFE-CMR device 900A is λ. Further, each of the first and second top electrode layers 941 and 942 may be approximately half the aggregate wavelength thickness of the corresponding composite top electrode 940′ (e.g., approximately λ/4), although the respective thicknesses of the first and second top electrode layers 941 and 942 may vary, as would be apparent to one skilled in the art. In addition, referring to the composite top electrode 940′, the first top comb electrode 810 is a signal electrode, and the second top comb electrode 820 is a top ground electrode.

The bottom electrode 910 includes the first bottom comb electrode 830 and the second bottom comb electrode 840, each of which is formed of a single layer of conductive material(s), exemplary compositions of which are as discussed above. The first bottom comb electrode 830 is another signal electrode, and the second bottom comb electrode 840 is another ground electrode. In the depicted embodiment, the spaces between the first and second bottom bus bars 835 and 845 and the second and first bottom fingers 831 and 841 of the bottom electrode 910 are respectively filled with a dielectric material (as opposed to being air spaces), such as NEBSG or non-conductive SiC, for example. These filled spaces include space 837 between the second bottom bus bar 845 and the first bottom finger 831, space 838 between the first and second bottom fingers 831 and 841, and space 839 between the second bottom finger 841 and the first bottom bus bar 835. The spaces 837-839 are at least partially aligned with the spaces 818 between the first top fingers 811, 812 and the second top fingers 821, 822, respectively. Also, the first bottom finger 831 is at least partially aligned with the second top finger 821, and the second bottom finger 841 is at least partially aligned with the first top finger 812. However, the relative placements of the bottom spaces 837-839 and the top spaces 818, as well as the relative placements the first and second bottom fingers 831, 841 and the first and second top fingers 811, 812, 821, 822, may vary without departing from the scope of the present teachings.

Referring to FIG. 9C, TFE-CMR device 900C substantially combines the configurations of the TFE-CMR devices 900A and 900B. That is, the TFE-CMR device 900C includes both the composite bottom electrode 910′ and the composite top electrode 940′. The composite bottom electrode 910′ includes the first bottom electrode layer 911 adjacent piezoelectric layer 230′ and the second top electrode layer 912 adjacent the first bottom electrode layer 911, and the composite top electrode 940′ includes first top electrode layer 941 adjacent the piezoelectric layer 230′ and second top electrode layer 942 adjacent the first top electrode layer 941. In the depicted embodiment, the composite bottom electrode 910′ has a thickness of approximately λ/2, the composite top electrode 940′ has a thickness of approximately λ/2, and the piezoelectric layer 230′ also has a thickness of approximately λ/2. Accordingly, the aggregate thickness of the acoustic stack of the TFE-CMR device 900C is 3λ/2.

Referring to FIG. 9D, TFE-CMR device 900D is substantially the same as TFE-CMR device 900A, except that the acoustic reflector is implemented as an acoustic mirror, such as the representative DBR 270, as opposed to the cavity 208. In this configuration, the DBR 270 is disposed on the substrate 205, the composite bottom electrode 910′ is disposed on the DBR 270, the piezoelectric layer 230 is disposed on the composite bottom electrode 910′, and the top electrode 440 is disposed over the piezoelectric layer 230. Of course, the DBR 270 may likewise be substituted for the cavity 208 in the TFE-CMR device 900B and the TFE-CMR device 900C, without departing from the scope of the present teachings.

While example embodiments are disclosed herein, one of ordinary skill in the art appreciates that many variations that are in accordance with the present teachings are possible and remain within the scope of the appended claims. For instance, as indicated above, the location, dimensions, and materials of a collar and/or frames can be variously altered. In addition, other features can be added and/or removed to further improve various performance characteristics of the described devices. These and other variations would become clear to one of ordinary skill in the art after inspection of the specification, drawings and claims herein. The invention therefore is not to be restricted except within the spirit and scope of the appended claims.

1. An acoustic resonator device, comprising:
a substrate;
a bottom electrode disposed on an acoustic reflector formed in or on the substrate;
a piezoelectric layer disposed over the bottom electrode; and
a top electrode disposed over the piezoelectric layer, the top electrode comprising:
a first top comb electrode comprising a first top bus bar and a plurality of first top fingers extending in a first direction from the first top bus bar; and
a second top comb electrode comprising a second top bus bar and a plurality of second top fingers extending in a second direction from the second top bus bar, the second direction being substantially opposite to the first direction such that the first and second top fingers form a top interleaving pattern,
wherein one of the bottom electrode and the top electrode comprises a composite electrode having a thickness of approximately λ/2, λ being a wavelength corresponding to a thickness extensional resonance frequency of the acoustic resonator, and
wherein the piezoelectric layer and one of the bottom electrode and the top electrode not comprising the composite electrode have a combined thickness of approximately λ/2.

2. The acoustic resonator device of claim 1, wherein the one of the bottom electrode and the top electrode comprising the composite electrode comprises:
a first electrode layer of first material having low acoustic impedance, formed adjacent to the piezoelectric layer; and
a second electrode layer of second material having high acoustic impedance, formed adjacent to the first electrode layer.

3. The acoustic resonator device of claim 2, wherein the first electrode layer comprises one of aluminum, titanium or beryllium, and
wherein the second electrode layer comprises one of tungsten, molybdenum or iridium.

4. The acoustic resonator device of claim 2, wherein each of the first electrode layer and the second electrode layer has a thickness of approximately λ/4.

5. The acoustic resonator device of claim 1, wherein the acoustic reflector comprises an air cavity formed in the substrate, and wherein the bottom electrode is disposed on the substrate over the air cavity.

6. The acoustic resonator device of claim 1, wherein the acoustic reflector comprises a distributed Bragg reflector (DBR) disposed on the substrate, and wherein the bottom electrode is disposed on the DBR.

7. The acoustic resonator device of claim 2, wherein the first top comb electrode is a signal electrode to which an electrical signal is applied, and the second top comb electrode is a floating electrode providing an output for the electrical signal, and
wherein at least a portion of the bottom electrode is grounded, such that the acoustic resonator device comprises a single-ended laterally coupled resonators filter (LCRF).

8. The acoustic resonator device of claim 7, wherein the bottom electrode comprises:
a first bottom comb electrode comprising a first bottom bus bar and at least one first bottom finger extending in a first direction from the first bottom bus bar; and
a second bottom comb electrode comprising a second bottom bus bar and at least one second bottom finger extending in a second direction from the second bottom bus bar, the second direction being substantially opposite to the first direction such that the first and second bottom fingers form a bottom interleaving pattern,
wherein the first bottom comb electrode is a ground electrode, and the second bottom comb electrode is another floating electrode providing another output for the electrical signal, such that the acoustic resonator device comprises a differential LCRF.

9. The acoustic resonator device of claim 2, wherein the first top comb electrode is a signal electrode to which an electrical signal is applied, and the second top comb electrode is a ground electrode, and
wherein the bottom electrode is left floating, such that the acoustic resonator device comprises a lateral-field-excitation (LFE) contour mode resonator (CMR).

10. The acoustic resonator device of claim 2, wherein the bottom electrode comprises:
a first bottom comb electrode comprising a first bottom bus bar and at least one first bottom finger extending in a first direction from the first bottom bus bar; and
a second bottom comb electrode comprising a second bottom bus bar and at least one second bottom finger extending in a second direction from the second bottom bus bar, the second direction being substantially opposite to the first direction such that the first and second bottom fingers form a bottom interleaving pattern,
wherein the first bottom comb electrode is another signal electrode, and the second bottom comb electrode is another ground electrode, such that the acoustic resonator device comprises a thickness-field-excitation (TFE) contour mode resonator (CMR).

11. The acoustic resonator device of claim 2, wherein the top electrode comprises the composite electrode having the thickness of approximately λ/2, and
wherein the piezoelectric layer and the bottom electrode have the combined thickness of approximately λ/2.

12. The acoustic resonator device of claim 2, wherein the bottom electrode comprises the composite electrode having the thickness of approximately λ/2, and
wherein the piezoelectric layer and the top electrode have the combined thickness of approximately λ/2.

13. An acoustic resonator device, comprising:
a substrate;
a bottom electrode disposed on an acoustic reflector formed in or on the substrate;
a piezoelectric layer disposed over the bottom electrode; and
a top electrode disposed over the piezoelectric layer, the top electrode comprising:
a first top comb electrode comprising a first top bus bar and a plurality of first top fingers extending in a first direction from the first top bus bar; and
a second top comb electrode comprising a second top bus bar and a plurality of second top fingers extending in a second direction from the second top bus bar, the second direction being substantially opposite to the first direction such that the first and second top fingers form a top interleaving pattern,
wherein each of the bottom electrode and the top electrode comprises a composite electrode having a thickness of approximately λ/2, λ being a wavelength corresponding to a thickness extensional resonance frequency of the acoustic resonator, and
wherein the piezoelectric layer has a thickness of approximately λ/2.

14. The acoustic resonator device of claim 13, wherein each of the bottom composite electrode and the top composite electrode comprises:
a first electrode layer of first material having low acoustic impedance, formed adjacent to the piezoelectric layer; and
a second electrode layer of second material having high acoustic impedance, formed adjacent to the first electrode layer.

15. The acoustic resonator device of claim 14, wherein the first top comb electrode is a signal electrode to which an electrical signal is applied, and the second top comb electrode is a floating electrode providing an output for the electrical signal, and
wherein at least a portion of the bottom electrode is grounded, such that the acoustic resonator device comprises a single-ended laterally coupled resonators filter (LCRF).

16. The acoustic resonator device of claim 15, wherein the bottom electrode comprises:
a first bottom comb electrode comprising a first bottom bus bar and at least one first bottom finger extending in a first direction from the first bottom bus bar; and
a second bottom comb electrode comprising a second bottom bus bar and at least one second bottom finger extending in a second direction from the second bottom bus bar, the second direction being substantially opposite to the first direction such that the first and second bottom fingers form a bottom interleaving pattern,
wherein the first bottom comb electrode is a ground electrode, and the second bottom comb electrode is another floating electrode providing another output for the electrical signal, such that the acoustic resonator device comprises a differential LCRF.

17. The acoustic resonator device of claim 14, wherein the first top comb electrode is a signal electrode to which an electrical signal is applied, and the second top comb electrode is a ground electrode, and
wherein the bottom electrode is left floating, such that the acoustic resonator device comprises a lateral-field-excitation (LFE) contour mode resonator (CMR).

18. The acoustic resonator device of claim 14, wherein the bottom electrode comprises:
a first bottom comb electrode comprising a first bottom bus bar and at least one first bottom finger extending in a first direction from the first bottom bus bar; and
a second bottom comb electrode comprising a second bottom bus bar and at least one second bottom finger extending in a second direction from the second bottom bus bar, the second direction being substantially opposite to the first direction such that the first and second bottom fingers form a bottom interleaving pattern,
wherein the first bottom comb electrode is another signal electrode, and the second bottom comb electrode is another ground electrode, such that the acoustic resonator device comprises a thickness-field-excitation (TFE) contour mode resonator (CMR).

19. The acoustic resonator device of claim 14, wherein the acoustic reflector comprises an air cavity formed in the substrate, and the bottom electrode is disposed on the substrate over the air cavity.

20. The acoustic resonator device of claim 14, wherein the acoustic reflector comprises a distributed Bragg reflector (DBR) disposed on the substrate, and the bottom electrode is disposed on the DBR.
